(19) United States
(12) Patent Application Publication
(10) Pub. No.: US 2026/0310869 A1
(43) Pub. Date: Oct. 8, 2026

(54) AI AGENT-BASED ANALYSIS OF DEBUGGING REPORTS FOR CIRCUIT DESIGN SYSTEMS AND APPLICATIONS

(71) Applicant: NVIDIA Corporation, Santa Clara, CA (US)

(72) Inventors: Jatin Sunil NAINANI, Amherst, MA (US); Anirudh Dhurka, Pleasanton, CA (US); Chia-Tung Ho, San Jose, CA (US)

(21) Appl. No.: 19/172,330

(22) Filed: Apr. 7, 2025

(51) Int. Cl. G06F 30/3315; G06F 30/27

(52) U.S. Cl. CPC G06F 30/3315; G06F 30/27

(57) ABSTRACT

In various examples, machine learning model agent-based analysis of debugging reports for circuit design systems and applications is disclosed. A multi-file report analysis agent may analyze the original structure of individual timing reports to construct a structured report database for the set of reports. Based on the individual reports incorporated into the structured report database, the report analysis agent may construct a TDRG that connects the individual reports based on relationships. An MCMM planner agent may decompose the user-provided evaluation task inputs into sub-tasks for multiple corners and modes and call a TDRG traversal agent to resolve individual sub-tasks, as indicated by a mode plan. The TDRG traversal agent prompts expert report agents to retrieve information from the structural report database based on traversing the TDRG. An expert report agent may generate data retrieval code that may be executed to query the specified report from the structured report database.

### BACKGROUND

Very Large-Scale Integration (VLSI) circuit design and optimization require extensive timing analysis and debugging to ensure functional correctness. Silicon failures in advanced VLSI technologies can be costly, making rigorous signoff analysis an important step to avoid critical timing and noise issues. Timing analysis is a complex verification method used as the basis for the final signoff, indicating that a chip design is ready for fabrication at the semiconductor foundry. Electronic design automation (EDA) tools, such as timing analysis tools, are often used to cover gate-level Static Timing Analysis (STA), detailed transistor-level STA, and variation analysis for VLSI designs, including intricate custom designs. Such tools can assist a circuit designer in determining whether a design can be expected to function at target operating frequencies by stressing a chip design at different conditions (e.g., different temperatures, different voltages, different processes, etc.), often referred to as corners.

### SUMMARY

Embodiments of the present disclosure relate to artificial intelligence (AI) agent-based analysis of debugging reports for circuit design systems and applications.

In contrast to conventional circuit design analysis systems, the systems and methods of the present disclosure provide for a multi-file report analysis agent that comprises a hierarchical, multi-agent large language model (LLM)-based framework designed to automate the analysis of multi-file reports, such as multi-corner multi-mode (MCMM) timing reports generated by timing analysis tools. A multi-file report analysis agent may integrate hierarchical plan solving and multi-agent collaboration to automate the analysis of reports such as MCMM timing reports generated by timing verification tools, and may include one or more of an MCMM planner agent, a timing debug relation graph (TDRG) traversal agent, and an expert report agent. To initialize the agent to evaluate a set of MCMM timing reports, the multi-file report analysis agent may analyze the original structure of individual timing reports to construct a structured report database for the set of reports. Based on the individual reports incorporated into the structured report database, the multi-file report analysis agent may construct a timing debug relation graph (TDRG) that connects the individual reports with the relation of debug knowledge from timing experts. The MCMM planner agent may comprise a mode planner agent that decomposes the user-provided evaluation task inputs (e.g., evaluation task queries requested by a user as inputs to the multi-file report analysis agent) into sub-tasks for each corner and mode. The MCMM planner agent may call the TDRG traversal agent to resolve individual sub-tasks, as indicated by a mode plan. The TDRG traversal agent activates (e.g., sends prompts to) one or more of the expert report agents to retrieve information from one or more reports of the structural report database, obtaining data for a response by jumping between individual reports based on traversing the TDRG.

In some embodiments, for different types of reports, the multi-file report analysis agent may comprise a respective specific expert report agent that knows how to query that specific report. An expert report agent, based on the task specified by the TDRG traversal agent for a report, may generate data retrieval code of a specified format (e.g., such as but not limited to Python code) providing an algorithm that may be executed by the multi-file report analysis agent to query the specified report from the structured report database. After retrieving a final result for a sub-task, the expert report agents may summarize the retrieved information and provide the answer to the query (e.g., sub-task) back to the TDRG traversal agent as sub-task response data. The TDRG traversal agent may summarize the sub-task response data results obtained from the respective expert report agent(s), sending the resulting response data summaries to the MCMM planner agent. The MCMM planner agent may then analyze and compile the summaries of sub-task response data obtained from the TDRG traversal agent for each planned corner and mode, generating a comprehensive final answer for use as the query response.

### BRIEF DESCRIPTION OF THE DRAWINGS

The present systems and methods for AI agent-based analysis of debugging reports for circuit design systems and applications are described in detail below with reference to the attached drawing figures, wherein:

FIG. 1 is a data flow diagram for an example process for a circuit design testing system comprising a multi-file report analysis agent, in accordance with some embodiments of the present disclosure;

FIG. 2 is a data flow diagram for an example multi-file report analysis agent, in accordance with some embodiments of the present disclosure;

FIG. 3 is a flow chart diagram for an example method for a multi-file report analysis agent, in accordance with some embodiments of the present disclosure;

FIG. 4A is a block diagram of an example generative language model system suitable for use in implementing at least some embodiments of the present disclosure;

FIG. 4B is a block diagram of an example generative language model that includes a transformer encoder-decoder suitable for use in implementing at least some embodiments of the present disclosure;

FIG. 4C is a block diagram of an example generative language model that includes a decoder-only transformer architecture suitable for use in implementing at least some embodiments of the present disclosure;

FIG. 5 is a block diagram of an example computing device suitable for use in implementing at least some embodiments of the present disclosure; and

FIG. 6 is a block diagram of an example data center suitable for use in implementing at least some embodiments of the present disclosure.

### DETAILED DESCRIPTION

Systems and methods are disclosed related to machine learning model agent-based analysis of debugging reports for circuit design systems and applications.

Typically, when a timing analysis for a Very Large-Scale Integration (VLSI) circuit design is performed, the analysis is run across an entire circuit and for multiple corners (e.g., different sets of conditions). Individual corners of the analysis may specify different testing modes, such as read mode, write mode, and scan mode. A mode may represent a cluster of different functionalities that may be accessed in a circuit design that cannot be analyzed together with another mode (e.g., a first mode may evaluate read operations from a memory while a second mode evaluates operations that write to the memory). For each corner and mode, the timing analysis may produce various reports, including maximum (max) and minimum (min) timing reports, crosstalk interference reports (xtalk max and xtalk min), clock signal timing reference reports, circuit operating frequency reports, and logic constraints (LC) reports. These reports are used by timing engineers to debug potential timing issues in a VLSI circuit design.

As chip manufacturing technology has advanced to smaller feature sizes (e.g., less than 5 nanometers (nm)), the increasing number of transistors, more complex VLSI circuit designs, and amplified effects of crosstalk have introduced significant challenges to timing analysis and debugging. These factors have resulted in the generation of multi-corner multi-mode (MCMM) timing reports from available timing analysis tools that are increasingly dense—to the point that it may become impossible for a human chip designer to fully appreciate the implications of the report results to a circuit design and whether an evaluated design meets target goals. For example, a routinely run timing report, such as a max or xtalk max timing report, may comprise over 16,000 timing paths for an industrial circuit design. This density makes it increasingly difficult and time-consuming for even experienced human designers to debug timing and/or other issues affecting circuit performance. Moreover, analysis and debugging involves flexible, multi-hop retrieval and reasoning across multiple reports and corners, beyond what a fixed script can automate. Since circuit design is an iterative process that involves identifying deficiencies, adjusting the design, and then rerunning the analysis, the ability to accurately understand issues identified from timing analysis reports can have a significant impact on product design timelines as well as development costs.

Large Language Models (LLMs) are a developing technology adaptable to various tasks in language understanding and interactive decision-making, incorporating reasoning and actions. Recent advances have explored the use of LLMs as agents for interactive decision-making. For example, LLMs have been proposed for repository-level code editing and completion, as well as for analyzing code to generate comprehensive documentation across entire code repositories. While LLMs have demonstrated utility in parsing a large body of data, applying LLMs to large-scale, multi-file structured data remains a significant challenge due to the complexity and scale of such datasets. Available solutions lack the domain knowledge necessary to handle various timing report types (e.g., path delay, crosstalk, logic constraints, etc.) simultaneously. Additionally, MCMM timing report analysis remains an unsolved and challenging task because the context of multi-report analysis often exceeds the token limits of current state-of-the-art LLMs and requires a wide variety of queries across different types of timing reports.

In contrast to prior approaches, embodiments of this present disclosure provide for a report analysis agent (e.g., a timing analysis agent) that comprises a hierarchical, multi-agent LLM-based framework designed to automate the analysis of multi-file reports, such as MCMM timing reports generated by timing analysis tools.

As described herein, in various embodiments, the disclosed multi-file report analysis agent seeks to significantly reduce the time spent debugging and analyzing timing reports —while increasing coherent understanding of implications of these reports, and may incorporate the expertise of experienced engineers and artificial intelligence (AI) techniques to generate insightful analysis for debugging timing issues with high accuracy and less variance. A multi-file report analysis agent may integrate hierarchical plan solving and multi-agent collaboration to automate the analysis of MCMM timing reports generated by timing verification tools and may include one or more of an MCMM planner agent, a timing debug relation graph (TDRG) traversal agent, and an expert report agent. This framework may implement a hierarchical workflow pipeline that starts with mode planning, followed by multi-report traversal, single-report information retrieval, and then providing the final answer.

As discussed herein, the MCMM planner agent may initially decompose evaluation task inputs (e.g., evaluation task queries requested by a user as inputs to the multi-file report analysis agent) into a list of corner and mode specified sub-tasks. The TDRG traversal agent generates a report retrieval plan, calls on one or more expert report agents to retrieve information from the multiple MCMM timing reports, and summarizes the fetched data from multiple reports on a distilled TDRG. The MCMM planner agent may then receive and compile the responses obtained from the sub-tasks, and returns a final answer in response to the initial queries (e.g., to the user). In some embodiments, agentic retrieval-augmented generation (RAG) may be applied to leverage coding capabilities of LLMs to retrieve necessary timing information from the timing reports while excluding irrelevant data.

To initialize the multi-file report analysis agent to evaluate a set of MCMM timing reports, the multi-file report analysis agent may analyze the original structure of individual timing reports to construct a structured report database for the set of reports. For example, in some embodiments, a structured report database may be organized into one or more nested dictionaries corresponding to each report type. For example, a structured report database for a max timing report may be organized based on key attributes of that report type (e.g., Summary, Data Info, Clock Info, Data Stages, Clock Stages, etc.), allowing for efficient and informed access by the multi-file report analysis agent. As an example, the Summary attribute for a report may define high-level path information (e.g., startpoints, endpoints, path identifiers (path IDs), slacks, etc.), while the Data Info and/or Clock Info attributes may summarize timing arc information (e.g., path-based slack adjustments (PBSAs), data arrival times, etc.). A detailed timing table for each timing arc may be stored in the Data Stages and Clock Stages attributes. The structured report database thus represents the body of authoritative data from which responses to evaluation task queries may be generated.

Moreover, to provide a structured strategy for retrieving relevant information from the structured report database, the multi-file report analysis agent may apply domain knowledge to analyze each report, as represented by at least one debugging trace. The debugging trace may indicate what kind of information may be retrieved from each report incorporated into the structured report database. The debugging trace comprises a structure that represents a generalized strategy for methodically progressing through a set of reports to perform one or more particular analysis tasks, and may be generated by one or more timing experts (e.g., experienced timing engineers and/or machine learning models trained to generate strategies for timing analysis tasks). That is, a debugging trace may outline the timing tasks designated by the timing experts to create a benchmark from industrial designs for evaluating performance, categorizing them into single-report and multi-report tasks.

Based on the individual reports incorporated into the structured report database, the multi-file report analysis agent may construct a timing debug relation graph (TDRG) that connects the individual reports with the relation of debug knowledge from timing experts. A relation graph (often referred to as a directed relation graph (DRG)) is a visual representation of relationships between different entities, where nodes represent the entities and edges (arrows) indicate the direction of the relationship between them. The multi-file report analysis agent may leverage the TDRG to dynamically traverse and retrieve information on nets, paths, or instances across multiple timing reports to solve tasks. In the TDRG, nodes of the graph represent the individual reports, while edges of the graph define the relationships between the debug information that may be used to traverse the TDRG. The multi-file report analysis agent may use the TDRG to dynamically traverse and retrieve information on nets, paths, or instances in multi-reports for task solving. In some embodiments, individual nodes of the TDRG may describe, for example, the timing attributes, type of timing table, and the usage of the corresponding report. For example, the description of a wire report node includes details such as the “Worst Coupling” attributes and the calculation of coupling mismatch. On the other hand, the edge descriptions capture distilled knowledge from the debugging trace, describing the relationships between different types of reports (e.g., an edge relationship between xtalk and RLC reports).

As previously mentioned, the multi-file report analysis agent may include one or more of an MCMM planner agent, a timing debug relation graph (TDRG) traversal agent, and an expert report agent. The MCMM planner agent may comprise a mode planner agent that decomposes the user-provided evaluation task inputs (e.g., evaluation task queries requested by a user as inputs to the multi-file report analysis agent) into sub-tasks for each corner and mode. Evaluation task inputs may involve single-report tasks and/or multi-report tasks. These are the responses to queries directed at specific reports that are inside specific modes and corners incorporated by the structured report database—made traversable by the TDRG to ascertain which reports hold relevant information to answer a query. In some embodiments, the evaluation task inputs may be input as a natural language query that is parsed by the mode planner agent based on natural language processing (e.g., using an LLM). For example, the mode planner agent may be implemented as least in part as an LLM-based agent. If the LLM-based mode planner agent is not confident regarding which mode the user is querying about (e.g., based on a confidence threshold), the mode planner agent can request clarification from the user at that point to make sure the relevant reports from the structured report database will be accessed to respond to the user's query.

The MCMM planner agent may prepare responses to evaluation task input queries that involve single-report tasks and/or multi-report tasks. Single-report tasks (e.g., tasks that can be completed based on data from a single report) may use domain knowledge of the type of report being analyzed and an understanding of its intricate structure, and may be divided into two categories. A first category may involve a query regarding group timing paths based on specific criteria. Such single-report tasks commonly involve, as non-limiting examples, retrieving paths between a start point and an endpoint, identifying paths with specific constraint values, and/or finding paths that start with specific edges across data and clock arcs. Some single-report tasks may perform complex queries to retrieve specific sets of problematic paths that need further investigation, while others may focus on deeply examining individual paths to identify issues. The second category may involve performing mathematical and/or string operations on a group of paths: These tasks usually involve performing operations (e.g., maximum, minimum, or average) on columns or high-level attributes of a report. For example, such a task might compare the worst values of different attributes across multiple paths or find the top-K paths with timing issues.

The process of completing multi-report tasks (e.g., tasks that are completed based on data from a plurality of reports) often involves gathering data from various types of reports (e.g., max, xtalk max, etc.) and performing reasoning based on data across reports to derive a final conclusion and/or response. For example, detecting missing clock signals in a timing path for a specified corner and mode may require cross-referencing the clock signals in the “clk” report and timing tables in the “max” report. Another multi-report task example involves identifying unusual coupling between victim and aggressor nets in a timing path. This first may require finding the most significant “aggressor” and “victim” nets in an xtalk report. Then, a next step may involve investigating the high resistance and capacitance (RC) mismatch and any abnormal logic constraints between the identified aggressor and victim nets in the wire and resistance, inductance, and capacitance (RLC) reports, respectively. In this example, a coupling mismatch may be determined by subtracting the worst-case coupling values. To perform analysis across an MCMM report, a multi-report task may be conducted in various corners and modes. The results may then be summarized, providing explanations for any potential causes of identified problems across all corners and modes.

In some embodiments, to allow the mode planner agent to divide the evaluation tasks given by the user across the appropriate corners and modes, the mode planner agent may call on one or more functions to explore the structural report database. For example, a get_corner_options function provides the mode planner agent with the names of the corners so that it may select the reports with corners relevant to the task. The mode planner agent may also apply a regular expression pattern to the function to search for corners with specific values in their name (like corners with 0.94v). To distribute the tasks across the modes, the mode planner agent may call on a get_mode_options function. This function allows the mode planner agent to take a corner or a list of corners, and return the modes that have parsable file formats. Once the mode planner agent has the corners and modes that are relevant to the task, it may provide a mode plan for the TDRG traversal agent.

In some embodiments, the MCMM planner agent may call the TDRG traversal agent to resolve individual sub-tasks, as indicated by the mode plan, sequentially and/or in parallel. The TDRG traversal agent processes sub-tasks derived from the analysis task query entered into the MCMM planner agent by the user—generating a plan for retrieving information from reports corresponding to nodes of the TDRG. Based on the plan for retrieving information, the TDRG traversal agent activates (e.g., sends prompts to) one or more of the expert report agents to retrieve information from one or more reports of the structural report database, obtaining data for a response by jumping between individual reports based on traversing the TDRG.

The traversal agent may include several functions for using the TDRG. In some embodiments, the TDRG traversal agent may comprise a get_traversal_options function that allows the agent to determine which node of the TDRG it is currently on and what immediate traversal options it has (e.g., what are the edge connected neighboring nodes that it can move to). As such, the traversal options may also be accompanied with edge information, allowing the agent to make an informed traversal decision. This function may thus facilitate dynamic exploration of the structured report database by the TDRG traversal agent. Once the traversal agent has decided on a report (node) to move to, it can use a traverse_graph function to move to the selected report, from where it can activate an expert report agent and provide the expert report agent with a task to solve with a call_current_report_assistant function. In some embodiments, an input to the TDRG traversal agent includes the TDRG distilled from the debugging trace(s). In some embodiments, a prompt used as input to the traversal agent may include node and edge descriptions of the TDRG to allow the traversal agent to use the TDRG for informed traversal of reports of the structured report database.

As discussed above, the TDRG traversal agent is able to move between different reports of the structured report database using the TDRG. In some embodiments, for different types of reports, the multi-file report analysis agent may comprise a respective specific expert report agent that knows how to query that specific report. More particularly, in some embodiments, an expert report agent may function as a variation of an agentic RAG model to apply the coding capabilities of LLMs to retrieve the relevant information from a report (e.g., relevant to performing a task and/or sub-task of the user's query) without including extraneous data. An expert report agent, based on the task specified by the TDRG traversal agent for a report, may generate data retrieval code of a specified format (e.g., such as but not limited to Python code) providing an algorithm that may be executed by the multi-file report analysis agent to query the specified report from the structured report database. The expert report agent may generate flexible and adaptable code to answer the query indicated by a report agent prompt by accessing a report of the structural report database according to the specific task requirements. As such, the expert report agent (and/or LLMs used to implement the expert report agent) may answer a sub-task based on a relevant portion of a full report table, and does not need to process a full report table at one time.

For example, a typical report for custom blocks on an average VLSI chip design may comprise the order of 8,000 tables, where each table may include enough information to exceed the context length of an LLM. Moreover, timing reports, even after parsing, have a complex structure. For example, a timing report may comprise a list of dictionaries, where each dictionary contains a plurality of other dictionaries, and each dictionary includes a Pandas dataframe, containing different arcs of a path being examined. A generated data retrieval code may instead be used to process specific tables of a report (specific rows and columns) and perform various operations (analytics) and/or computations through the data retrieval code. The TDRG traversal agent may move through different nodes associated with different reports, and call on corresponding expert report agents to generate the data retrieval code for retrieving the relevant information from that report. Note that in some embodiments, the data retrieval codes from different expert report agents may be executed simultaneously and/or may be working in parallel to perform data retrieval and analysis computations from different reports.

In some embodiments, the expert report agent may be adaptively given information on the type of report it is working on and one or more code examples most relevant to solving the task. In some embodiments, the expert report agent may use the code examples to write data retrieval code effectively. The expert report agent may be provided with code examples that are relevant to the user task and the current report. For example, the expert report agent may have access to code examples for each report type, and as a report is loaded, the agent may be initialized with report information and one or more code examples most relevant to the task based on, for example, a RAG methodology. For example, in some embodiments, given the report type and tasks, an expert report agent may access (e.g., by prompting a RAG) a library of relevant code samples for reference in generating data retrieval codes. In some embodiments, the data retrieval code may be generated by the expert report agent based on Reasoning+Action (ReAct) prompting. That is, an expert report agent may evaluate the effectiveness of its own code; by reviewing results generated by an initial data retrieval code, the expert report agent may iteratively revise the code until it converges on a result that appears to provide a final result (e.g., an answer) from that report. When the expert report agent determines that the data retrieval code has converged on a final result, the result may be provided back to the TDRG traversal agent.

After retrieving a final result for a sub-task, the expert report agents may summarize the retrieved information and provide the answer to the query (e.g., sub-task) back to the TDRG traversal agent as sub-task response data. In some embodiments, the TDRG traversal agent may proceed to traverse the TDRG to query another expert report agent using information from sub-task response data previously retrieved by a previously prompted expert report agent. That is, when the traversal agent determines from retrieved information that another report has information relevant to completing a task, it may move to that node of the TDRG and call another expert report agent—which in turn generates data retrieval code tailored for retrieving information from the new report. The TDRG traversal agent may summarize the sub-task response data results obtained from the respective expert report agent(s), sending the resulting response data summaries to the MCMM planner agent. The MCMM planner agent may then analyze and compile the summaries of sub-task response data obtained from the TDRG traversal agent for each planned corner and mode, generating a comprehensive final answer for use as the query response.

In some embodiments, a multi-file report analysis agent and/or any of the discussed component agents of the multi-file report analysis agent discussed herein may be implemented by one or more language models (e.g., Meta Llama, NVIDIA NVLM, OpenAI GPT-4o, or other large language models) executed on one or more graphics processing units (GPUs) and/or other processing circuitry. For example, one or more of the MCMM planner agent, TDRG traversal agent, and/or one or more expert report agents may be implemented using one or more such language models. In some embodiments, the various distinct agents of the multi-file report analysis agent may be implemented by an LLM, where an individual agent is invoked within the LLM based on the prompt input to the LLM. That is, the LLM may effectively implement a particular component agent of the multi-file report analysis agent dynamically based on a prompt comprising an output from a prior agent (e.g., the MCMM planner agent may provide a prompt to the TDRG traversal agent, which may provide one or more prompts to the expert report agents). Moreover, one or more functions of the multi-file report analysis agent may be implemented as a network service (e.g., an LLM microservice) hosted by a cloud-based computing platform (e.g., a Kubernetes cluster), where a user subscribed to the service may incorporate functions of the multi-file report analysis agent exposed by the microserver into a circuit design workflow (e.g., an EDA workflow). For example, in some embodiments, one or more functions of the multi-file report analysis agent may be accessed as services by a client application using, for example, application programming interface (API) function calls. Moreover, at least one of the structured report database and/or timing debug relation graph (TDRG) may be hosted and accessed from one or more cloud-based computing platforms by the multi-file report analysis agent.

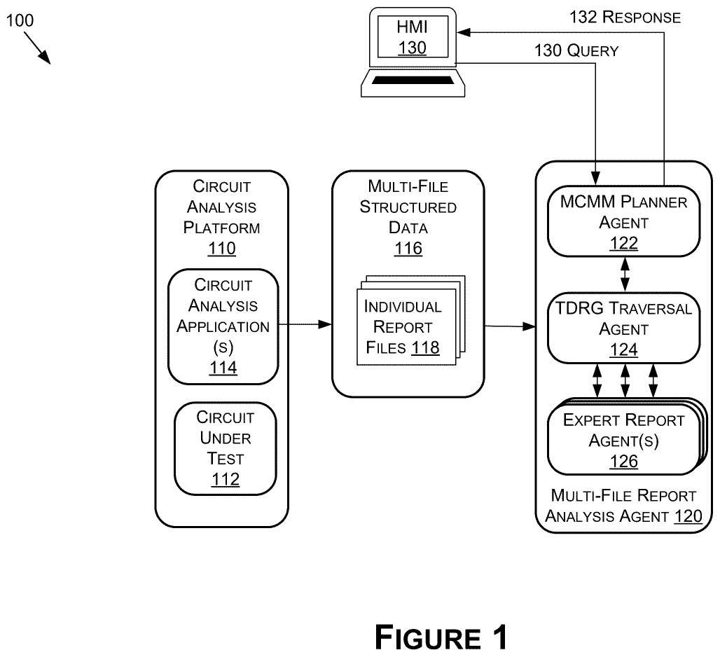

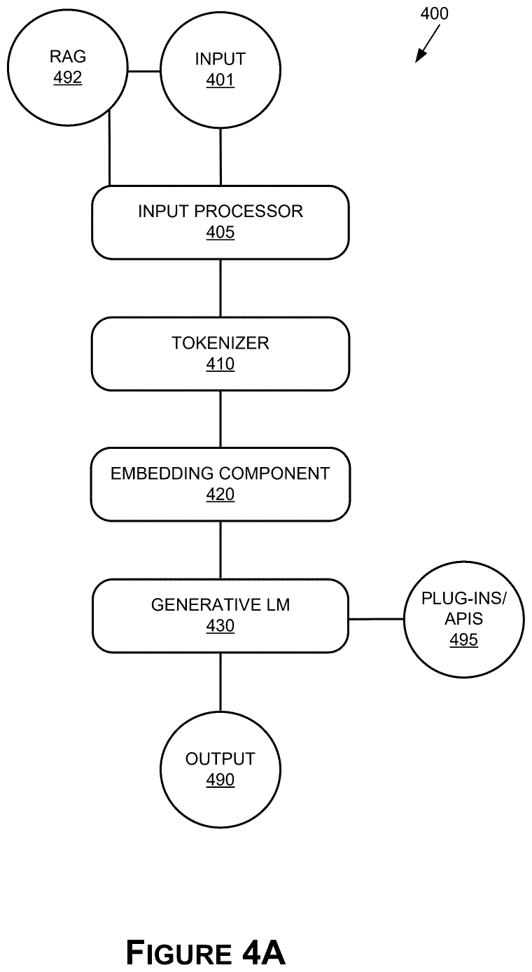

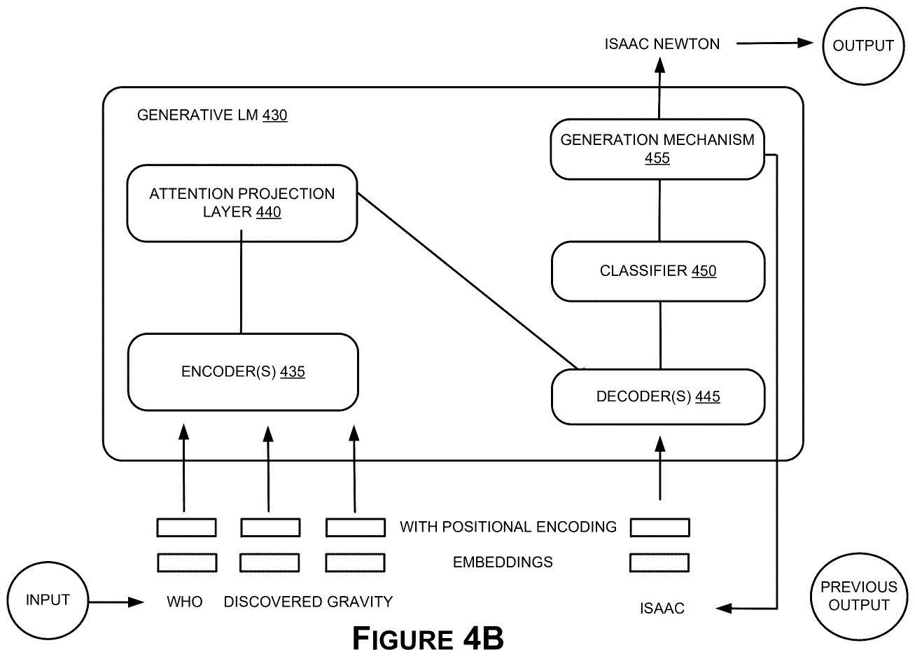

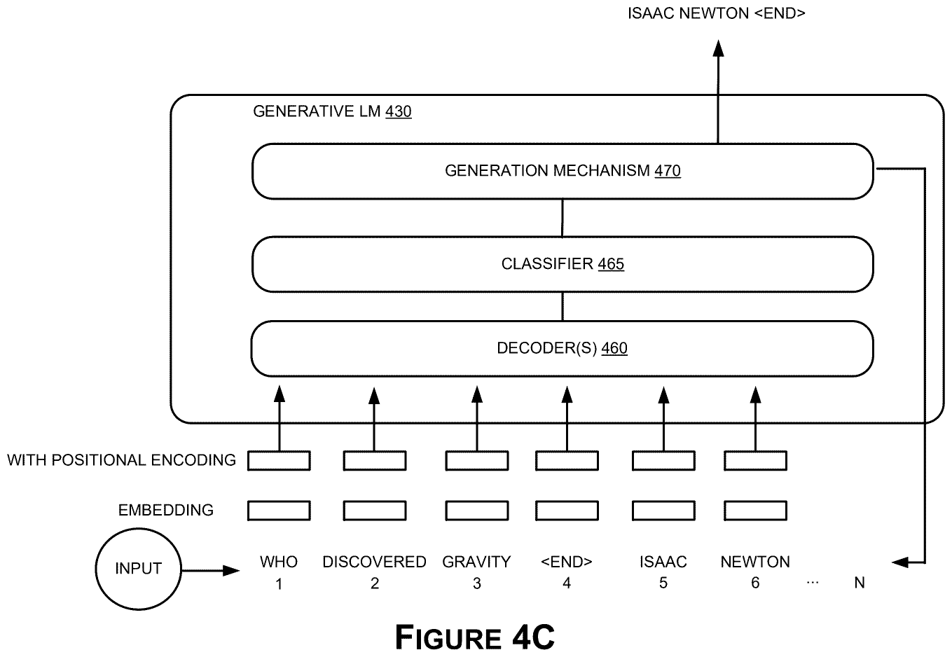

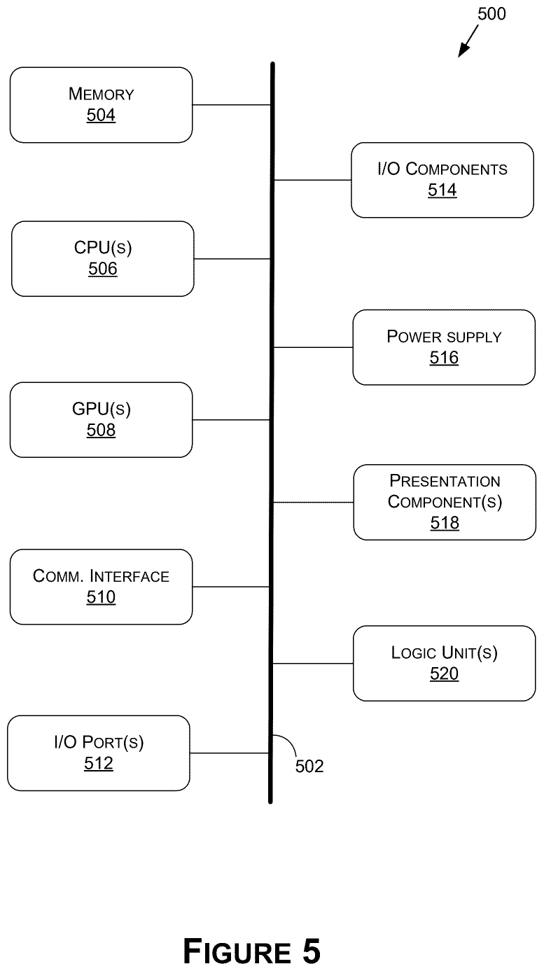

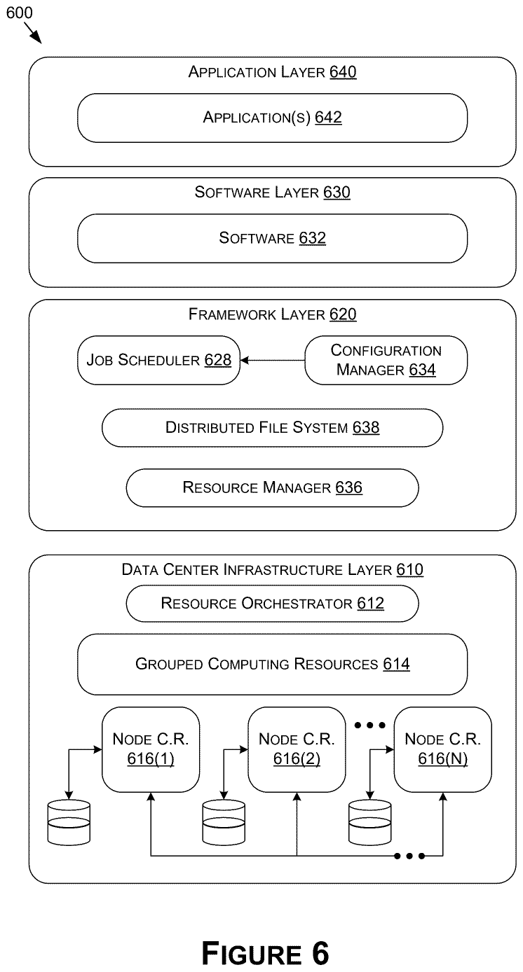

With reference to FIG. 1, FIG. 1 is an example data flow diagram for a process for a circuit design testing system 100 comprising a multi-file report analysis agent 120 (e.g., a timing analysis agent), in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out using one or more processors (e.g., processing units, processing circuitry, etc.) executing instructions stored in one or more memories. For example, in some embodiments, the system and methods described herein may be implemented using one or more generative language models (e.g., as described in FIGS. 4A-4C), one or more computing devices or components thereof (e.g., as described in FIG. 5), and/or one or more data centers or components thereof (e.g., as described in FIG. 6).

As shown in FIG. 1, circuit design testing system 100 may comprise a circuit analysis platform 110 that executes one or more circuit analysis applications 114 to perform testing (e.g., timing analysis) on a circuit under test 112. In some embodiments, the circuit under test 112 may comprise a VLSI circuit design, or other integrated circuits or chip technology, and the circuit analysis applications 114 may execute one or more circuit analysis tools (e.g., EDA tools) on the circuit under test 112. For example, circuit analysis tools may include, but are not limited to, timing analysis tools to perform STA, detailed transistor-level STA, and variation analysis for VLSI designs. In some embodiments, circuit analysis tools may generate multi-corner multi-mode (MCMM) timing reports that provide information about circuit performance such as, but not limited to, timing violations, slack, critical paths, setup/hold violations, clock skew, datapath delay, and/or other circuit performance metrics. As discussed, EDA tools such as the circuit analysis applications 114 generate test reports in the form of multi-file structured data 116, where the multi-file structured data 116 may comprise many individual report files 118 corresponding to the results of the tests performed over the various corners and modes of the circuit design.

In the form produced by the circuit analysis platform 110, the multi-file structured data 116 may comprise a complex structure of nested dictionaries and tables that is difficult and time-consuming for even experienced human designers to use to debug timing and/or other issues affecting circuit performance. As such, this disclosure presents embodiments of a multi-file report analysis agent 120 (e.g., a timing analysis agent) that comprises a hierarchical, multi-agent LLM-based framework (although LLMs are primarily described, other language model types may be additionally or alternatively be used, such as MMLMs and/or VLMs) designed to automate the analysis of multi-file reports, such as MCMM timing reports generated by EDA tools such as the circuit analysis applications 114. As discussed herein, the multi-file report analysis agent 120 may integrate hierarchical plan solving and multi-agent collaboration to automate the analysis of multi-file structured data 116 (e.g., MCMM timing reports generated by timing verification tools) and may include one or more of an MCMM planner agent 122, a timing debug relation graph (TDRG) traversal agent 124, and one or more expert report agents 126.

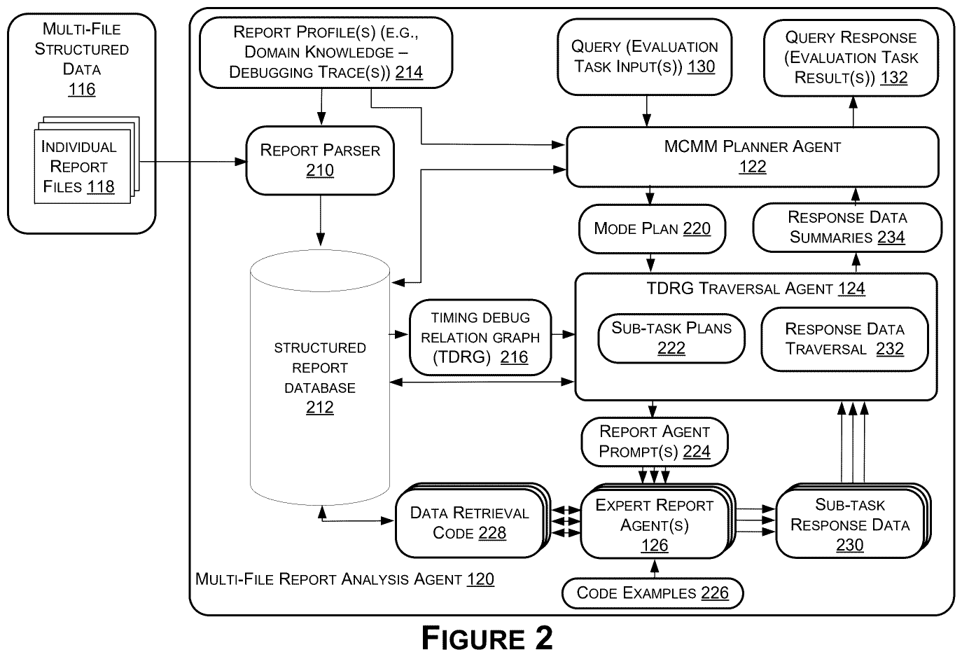

As described in greater detail with respect to FIG. 2 and elsewhere herein, the MCMM planner agent 122 may initially receive a user-generated query 130 (e.g., from a human-machine interface 134 of a computing device 500) defining one or more evaluation task inputs to the multi-file report analysis agent 120, which may be decomposed into a list of corner and mode specified sub-tasks. The TDRG traversal agent 124, based on a mode plan from the MCMM planner agent 122, may generate a report retrieval plan comprising one or more sub-task plans, and calls on one or more expert report agents 126 to retrieve information captured in the individual report files 118 of the multi-file structured data 116. Response data generated by the one or more expert report agents 126 may be consolidated and summarized and reported back to the user as a query response 132.

In the various embodiments described herein, the disclosed multi-file report analysis agent 120 beneficially reduces the time spent debugging and analyzing timing reports while increasing coherent understanding of implications of the reports generated by EDA tools such as the circuit analysis applications 114, thus rendering the circuit analysis applications 114 as more effective tools for debugging circuit designs and correspondingly reducing product development times.

FIG. 2 is an example data flow diagram providing further details for an example multi-file report analysis agent 120, in accordance with some embodiments of the present disclosure. As shown in FIG. 2, the multi-file report analysis agent 120 may receive the multi-file structured data 116 comprising the individual report files 118 produced by the circuit analysis platform 110, and representing the results of testing of the circuit under test 112.

In some embodiments, the multi-file report analysis agent 120 may perform an initialization to evaluate the individual report files 118 of the multi-file structured data 116. For example, the multi-file report analysis agent 120 may comprise a report parser 210 that inputs and evaluates the structure of individual report files 118 to construct a structured report database 212. In some embodiments, a structured report database 212 may be organized into one or more nested dictionaries corresponding to the individual report types of the individual report files 118. For example, a structured report database 212 for a max timing report may be organized based on key attributes of that report type (e.g., Summary, Data Info, Clock Info, Data Stages, Clock Stages, etc.), allowing for efficient and informed access by the multi-file report analysis agent. A Summary attribute for an individual report file 118 may define high-level path information (e.g., startpoints, endpoints, path IDs, slacks, etc.), while the Data Info and/or Clock Info attributes may summarize timing arc information (e.g., path-based slack adjustments (PBSA), data arrival times, etc.). A detailed timing table for each timing arc may be stored in the Data Stages and Clock Stages attributes for an individual report file 118 within the structured report database 212. The structured report database 212 thus represents the body of authoritative data from which responses to evaluation task queries may be generated. In some embodiments, the report parser 210 may generate the structured report database 212 based on one or more report profiles 214. The one or more report profiles 214 may correspond to the individual report files 118 generated by the circuit analysis applications 114 and may provide the report parser 210 with a structured strategy for retrieving relevant information from the structured report database 212. In some embodiments, the report parser 210 may apply domain knowledge to analyze each of the individual report files 118 as represented by at least one debugging trace. The debugging trace may indicate what kind of information may be retrieved from each report incorporated into the structured report database 212. The debugging trace comprises a structure that represents a generalized strategy for methodically progressing through a set of reports to perform one or more particular analysis tasks, and may be generated by one or more timing experts (e.g., experienced timing engineers and/or machine learning models trained to generate strategies for timing analysis tasks and/or other analysis guidance documents). As an example, a debugging trace provided by the one or more report profiles 214 may outline the timing tasks designated by the timing experts to create a benchmark from industrial designs for evaluating performance, categorizing them into single-report and/or multi-report tasks.

Based on the individual report files 118 incorporated into the structured report database 212, the multi-file report analysis agent 120 may construct a timing debug relation graph (TDRG) 216 that connects the individual report files 118 with the relations provided by debug knowledge from the one or more report profiles 214. The TDRG 216 defines a representation of relationships between different entities of the structured report database 212 where nodes represent the entities (e.g., reports, tables, dictionaries, etc.) and edges (arrows) indicate the direction of the relationship between them. The multi-file report analysis agent 120 may leverage the TDRG 216 to dynamically traverse and retrieve information from the structured report database 212 regarding nets, paths, and/or instances across multiple objects in the structured report database 212 (e.g., timing reports) to solve tasks in response to the query 130. In some embodiments, within the TDRG 216, nodes may represent the individual reports, while edges of the graph define the relationships between the debug information that may be used to traverse the TDRG 216. The multi-file report analysis agent 120 may use the TDRG 216 to dynamically traverse and retrieve information on nets, paths, or instances in multi-reports for task solving. In some embodiments, individual nodes of the TDRG 216 may describe, for example, the timing attributes, type of timing table, and the usage of the corresponding individual report file 118. The description of a wire report node may include details such as the “Worst Coupling” attributes and the calculation of any coupling mismatch. On the other hand, the edge descriptions capture distilled knowledge from the one or more report profiles 214 (e.g., debugging traces), describing the relationships between different types of reports (e.g., an edge relationship between xtalk and RLC reports).

As previously mentioned, the multi-file report analysis agent 120 may include one or more of an MCMM planner agent 122, a timing debug relation graph (TDRG) traversal agent 124, and one or more expert report agents 126. The MCMM planner agent 122 may implement a language model (e.g., LLM)-based mode planner agent that decomposes the user-provided evaluation task inputs of the query 130 into sub-tasks for each corner and mode. The evaluation tasks involved in answering a query 130 may involve single-report tasks and/or multi-report tasks. Such reports represent responses to queries directed at specific reports within the individual report files 118 that are inside specific modes and corners incorporated by the structured report database 212—made traversable by the TDRG 216 to ascertain which of the individual report files 118 hold relevant information to answer a query 130. In some embodiments, the query 130 may be input as a natural language query that is parsed by the MCMM planner agent 122 based on natural language processing (e.g., using an LLM). For example, the MCMM planner agent 122 may be implemented as least in part as an LLM-based agent (or other language model-based agent). In some embodiments, the MCMM planner agent 122 may generate a confidence score when evaluating the query 130 that indicates a confidence regarding which mode(s) the query 130 is querying about. When the confidence score indicates that the MCMM planner agent 122 is not confident in its understanding of the query 130 (e.g., the confidence score is less than a confidence threshold), the MCMM planner agent 122 can send a prompt back to the user to request clarification to make sure that relevant reports from the structured report database 212 will be accessed to respond to the user's query 130. As mentioned, the MCMM planner agent 122 may prepare a response to a query 130 that involves single-report tasks and/or multi-report tasks.

In some embodiments, to allow the MCMM planner agent 122 to divide the evaluation tasks given by the user across the appropriate corners and modes, MCMM planner agent 122 may call on one or more functions to explore the structural report database. For example, a get_corner_options function provides the MCMM planner agent 122 with the names of the corners so that it may select the reports with corners relevant to the task. The MCMM planner agent 122 may also apply a regular expression pattern to the function to search for corners with specific values in their name. To distribute the tasks across the modes, the MCMM planner agent 122 may call on a get_mode_options function. This function allows the MCMM planner agent 122 to take a corner or a list of corners, and return the modes that have parsable file formats. Moreover, the MCMM planner agent 122 may input the domain knowledge provided by the one or more report profiles 214 (e.g., one or more debugging traces) to define individual sub-tasks to be performed to gather the relevant data to produce the query response 132. Once the MCMM planner agent 122 has the corners and modes that are relevant to the task, it may produce and provide a mode plan 220 that indicates the individual sub-tasks.

In some embodiments, the MCMM planner agent 122 may call the TDRG traversal agent 124 to resolve the individual sub-tasks, as indicated by the mode plan 220. As discussed herein, individual sub-tasks may be selectively performed either sequentially, in parallel, or in combinations thereof. For example, sub-tasks that do not have dependencies on each other may be performed independently and simultaneously executed in parallel. In other cases where a sub-task is performed using results obtained from another sub-task, the sub-task may be performed sequentially to provide the latter sub-task with the requisite information from the prior sub-task.

In some embodiments, input to the TDRG traversal agent 124 includes the TDRG 216 and mode plan 220. In some embodiments, the mode plan 220 may comprise a prompt that includes node and edge descriptions of the TDRG 216 to allow the TDRG traversal agent 124 to use the TDRG 216 for informed traversal of reports of the structured report database 212. Based on the mode plan 220, the TDRG traversal agent 124 may use the relationships between reports as provided by the TDRG 216 to generate one or more sub-task plans 222 for retrieving information from reports corresponding to nodes of the TDRG 216. Based on the one or more sub-task plans 222, the TDRG traversal agent 124 may generate one or more report agent prompts 224 for input to the one or more expert report agents 126 to retrieve information from one or more reports of the structured report database 212, obtaining data for the query response 132 by jumping between the data provided by the individual report files 118 based on traversing the TDRG 216.

The TDRG traversal agent 124 may include several functions for leveraging the relationships between reports indicated by the TDRG 216. In some embodiments, the TDRG traversal agent 124 may comprise a get_traversal_options function that allows the agent to determine which node of the TDRG it is currently on and what immediate traversal options it has (e.g., what are the edge connected neighboring nodes that it can move to). Traversal options may include edge information, allowing the TDRG traversal agent 124 to make informed traversal decisions on how to move through the TDRG 216. Once the TDRG traversal agent 124 has identified which report (node) it should move to next, it can use a traverse_graph function to move to the selected report, from where it can activate an expert report agent 126 (e.g., corresponding to that report) and provide the expert report agent 126 with a report agent prompt 224 (e.g., with a call_current_report_assistant function) that defines the sub-task to solve as indicated by the one or more sub-task plans 222. As discussed above, the TDRG traversal agent 124 is able to move between different reports of the structured report database 212 using the TDRG 216 as a roadmap that indicates the relationships between the reports.

In some embodiments, for different types of reports, the multi-file report analysis agent 120 may comprise a respective specific expert report agent 126 that is designed to query that specific report type in order to obtain a relevant response (e.g., sub-task response data 230) to a report agent prompt 224. In some embodiments, an expert report agent 126 may function as a variation of an agentic RAG model to execute LLM-based code generation to produce data retrieval code 228 to probe the structured report database 212 and retrieve concise and relevant information from a report of the structured report database 212 (e.g., relevant to performing a sub-task as represented by a report agent prompt 224). An expert report agent 126, based on the report agent prompt 224 specified by the TDRG traversal agent 124, may generate data retrieval code 228 of a specified format (e.g., such as but not limited to Python code) providing an algorithm that may be executed by the multi-file report analysis agent 120 to query the specified report from the structured report database 212. The expert report agent 126 may generate flexible and adaptable code to answer the query indicated by the report agent prompt 224 by accessing a report of the structured report database 212 according to the specific sub-task requirements. As such, the expert report agent 126 (and/or LLMs used to implement the expert report agent 126) may answer a sub-task based on a relevant portion of a full report table, without the need to process a full report table at one time. A data retrieval code 228 generated by an expert report agent 126 may be used to process specific tables of a report (specific rows and columns) and perform various operations (analytics) and/or computations through the data retrieval code. The TDRG traversal agent 124 may move through different nodes associated with different reports, and through report agent prompt(s) 224, may call on corresponding expert report agents 126 to generate the data retrieval code 228 for retrieving the relevant information from that report. Note that in some embodiments, the data retrieval codes from different expert report agents may be executed simultaneously and/or work in parallel to perform data retrieval and analysis computations from different reports at the same time, increasing the efficiency of gathering data for producing the query response 132.

In some embodiments, an expert report agent 126 may be provided with information on the type of report it is working on and/or have access to one or more code examples 226 comprising samples of previously developed code relevant to solving the task. In some embodiments, the expert report agent 126 may use the code examples 226 to write data retrieval code 228 effectively. For example, the one or more expert report agents 126 may have access to code examples 226 for different report types included in the structured report database 212. In some embodiments, as a report is loaded to the structured report database 212 by the report parser 210, a corresponding expert report agent 126 may be initialized with report information and one or more code examples 226 most relevant to the task based on, for example, a RAG methodology. For example, in some embodiments, given the report type and tasks, an expert report agent 126 may access (e.g., by prompting a RAG) a library of relevant code samples for reference in generating data retrieval codes 228. In some embodiments, data retrieval code 228 may be generated by the expert report agent 126 based on Reasoning+Action (ReAct) prompting that combines logical reasoning with actionable steps and observations. In some embodiments, an expert report agent 126 may evaluate the effectiveness of its own data retrieval code 228. That is, by reviewing results generated by an initial data retrieval code 228, the expert report agent 126 may iteratively revise the code until it converges on a result that appears to provide a final result (e.g., an answer) from that report. When the expert report agent 126 determines that the data retrieval code 228 has converged on a final result, the result may be provided back to the TDRG traversal agent 124 as sub-task response data 230.

After retrieving the report information from the structured report database 212 for a final result for a sub-task, the expert report agents 126 may summarize the retrieved information and provide the answer to the report agent prompts 224 back to the TDRG traversal agent 124 as sub-task response data 230. In some embodiments, the TDRG traversal agent 124 may proceed to perform a response data traversal 232 to again traverse the TDRG 216 to prompt another expert report agent 126 using information from sub-task response data 230 retrieved by a previously prompted expert report agent 126. That is, the TDRG traversal agent 124 may determine from sub-task response data 230 and the TDRG 216 that another report of the structured report database 212 may have information relevant to completing a task. In that case, the TDRG traversal agent 124 may move to that node of the TDRG 216 and call another expert report agent 126 (e.g., using a report agent prompt 224)—which in turn generates additional data retrieval code 228 tailored retrieving information from the new report. Once a complete set of sub-task response data 230 has been obtained (e.g., the one or more sub-task plans 222 have been completed), the TDRG traversal agent 124 may produce response data summaries 234 that summarize the sub-task response data 230 results obtained from the respective expert report agent(s) 126, sending the resulting response data summaries 234 to the MCMM planner agent 122. The MCMM planner agent 122 may then analyze and compile the response data summaries 234 for each planned corner and mode, generating a comprehensive final answer for use as the query response 132.

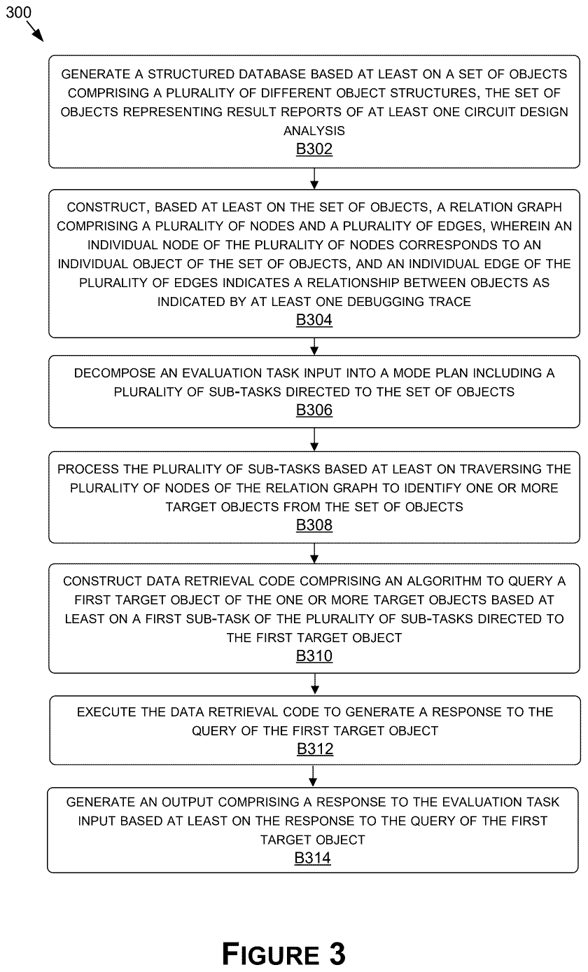

In some embodiments, a multi-file report analysis agent 120 and/or any of the discussed component agents of the multi-file report analysis agent 120 discussed herein may be implemented by one or more language models (e.g., Meta Llama, NVIDIA NVLM, OpenAI GPT-4o, or other language models) executed on one or more GPUs and/or other processing circuitry, such as described with respect to the computing device 500 of FIG. 5 and/or the data center 600 of FIG. 3. For example, one or more of the MCMM planner agent 122, TDRG traversal agent 124, and/or one or more expert report agents 126 may be implemented using one or more such language models. In some embodiments, the various distinct agents of the multi-file report analysis agent 120 may be implemented by an LLM, where an individual agent is invoked within the LLM based on the prompt input to the LLM. That is, the LLM may effectively implement a particular component agent of the multi-file report analysis agent 120 dynamically based on a prompt comprising an output from a prior agent (e.g., the MCMM planner agent may provide a prompt to the TDRG traversal agent, which may provide one or more prompts to the expert report agents). In some embodiments, one or more of the MCMM planner agent 122, TDRG traversal agent 124, and/or one or more expert report agents 126 may comprise a generative language model system 400 as described with respect to FIGS. 4A to 4C.

FIG. 3 is a flow diagram showing a method 300 for a multi-file report analysis agent, in accordance with some embodiments of the present disclosure. It should be understood that the features and elements described herein with respect to the method 300 of FIG. 3 may be used in conjunction with, in combination with, or substituted for elements of any of the other embodiments discussed herein and vice versa. Further, it should be understood that the functions, structures, and other descriptions of elements for embodiments described in FIG. 3 may apply to like or similarly named or described elements across any of the figures and/or embodiments described herein and vice versa.

Each block of method 300, described herein, comprises a computing process that may be performed using any combination of hardware, firmware, and/or software. For instance, various functions may be carried out by one or more processors comprising processing circuitry to execute instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 300 is described, by way of example, with respect to the circuit design testing system 100 and/or multi-file report analysis agent 120 as shown in FIGS. 1 and 2. However, the method may additionally or alternatively be executed by any one system, or any combination of systems, including, but not limited to, those described herein.

As discussed herein in greater detail, in some embodiments the method may generally include: generating an evaluation task output in response to a query of a structured database including a set of objects comprising a plurality of different object structures and representing result reports of at least one circuit design analysis of the evaluation task output generated based at least on: identifying one or more target objects based at least on traversing a plurality of nodes of a relation graph, the relation graph comprising a graph structure based at least on the set of objects and a debugging trace defining one or more structured strategies for retrieving information from the structured database, and executing a data retrieval code constructed by a language model in response to at least one prompt representing at least one sub-task of the query and an indication of the identified one or more target objects.

The method 300, at block B302, includes generating a structured database based at least on a set of objects comprising a plurality of different object structures, the set of objects representing result reports of at least one circuit design analysis. The set of objects may comprise representations of the individual report files 118 generated by circuit analysis applications 114 based on the evaluation of test 112 by the circuit analysis platform 110. In some embodiments, the set of objects comprises one or more of a timing report, a multi-corner multi-mode (MCMM) timing report, or a static timing analysis (STA) report. The circuit under test 112 may comprise a VLSI circuit design, or other integrated circuits or chip technology, and the circuit analysis applications 114 may execute one or more circuit analysis tools (e.g., EDA tools) on the circuit under test 112. Circuit analysis tools may include, as non-limiting examples, timing analysis tools to perform STA, detailed transistor-level STA, and/or variation analysis for VLSI designs. Circuit analysis tools may generate multi-corner multi-mode (MCMM) timing reports that provide information about circuit performance such as, but not limited to, timing violations, slack, critical paths, setup/hold violations, clock skew, datapath delay, and/or other circuit performance metrics. As discussed, EDA tools such as the circuit analysis applications 114 generate test reports in the form of multi-file structured data 116, where the multi-file structured data 116 may comprise many individual report files 118 corresponding to the results of the tests performed over the various corners and modes of the circuit design.

As discussed herein, in some embodiments, the multi-file report analysis agent 120 may perform an initialization to evaluate the individual report files 118 of the multi-file structured data 116. For example, the multi-file report analysis agent 120 may comprise a report parser 210 that inputs and evaluates the structure of individual report files 118 to construct a structured report database 212. The structured database comprises one or more nested dictionaries, wherein an individual dictionary of the one or more nested dictionaries corresponds to an associated object structure of the plurality of different object structures. In some embodiments, a structured report database 212 may be organized into one or more nested dictionaries corresponding to the individual report types of the individual report files 118. For example, a structured report database 212 for a max timing report may be organized based on key attributes of that report type (e.g., Summary, Data Info, Clock Info, Data Stages, Clock Stages, etc.) allowing for efficient and informed access by the multi-file report analysis agent. A Summary attribute for an individual report file 118 may define high-level path information (e.g., startpoints, endpoints, path IDs, slacks, etc.), while the Data Info and/or Clock Info attributes may summarize timing arc information (e.g., path-based slack adjustments (PBSAs), data arrival times, etc.). A detailed timing table for each timing arc may be stored in the Data Stages and Clock Stages attributes for an individual report file 118 within the structured report database 212. The structured report database 212 thus represents the body of authoritative data from which responses to evaluation task queries may be generated. In some embodiments, the report parser 210 may generate the structured report database 212 based on one or more report profiles 214.

The method 300, at block B304, includes constructing, based at least on the set of objects, a relation graph comprising a plurality of nodes and a plurality of edges, wherein an individual node of the plurality of nodes corresponds to an individual object of the set of objects, and an individual edge of the plurality of edges indicates a relationship between objects as indicated by at least one debugging trace. Based on the individual report files 118 incorporated into the structured report database 212, the multi-file report analysis agent 120 may construct a timing debug relation graph (TDRG) 216 that connects individual objects (e.g., individual report files 118) with the relation of debug knowledge from the one or more report profiles 214. The TDRG 216 defines a representation of relationships between different entities of the structured report database 212 where nodes represent the entities (e.g., reports, tables, dictionaries, etc.) and edges (arrows) indicate the direction of the relationship between them. The multi-file report analysis agent 120 may leverage the TDRG 216 to dynamically traverse and retrieve information from the structured report database 212 regarding nets, paths, and/or instances across multiple objects in the structured report database 212 (e.g., timing reports) to solve tasks in response to the query 130. The at least one debugging trace may indicate a generalized strategy for progressing through a set of analyses reports to perform one or more particular analysis tasks. The at least one debugging trace may be produced based on a compilation of analysis guidance documents. As an example, a debugging trace provided by the one or more report profiles 214 may outline the timing tasks designated by the timing experts to create a benchmark from industrial designs for evaluating performance, categorizing them into single-report and/or multi-report tasks. The debugging trace may indicate what kind of information may be retrieved from each report incorporated into the structured report database 212. The debugging trace comprises a structure that represents a generalized strategy for methodically progressing through a set of reports to perform one or more particular analysis tasks, and may be generated by one or more timing experts (e.g., experienced timing engineers and/or machine learning models trained to generate strategies for timing analysis tasks and/or other analysis guidance documents).

The method 300, at block B306, includes decomposing an evaluation task input into a mode plan including a plurality of sub-tasks directed to the set of objects. As an example, in some embodiments, the MCMM planner agent 122 may call the TDRG traversal agent 124 to resolve the individual sub-tasks, as indicated by the mode plan 220. The mode plan 220 may comprise a prompt that includes node and edge descriptions of the TDRG 216 to allow the TDRG traversal agent 124 to use the TDRG 216 for informed traversal of reports of the structured report database 212. Based on the mode plan 220, the TDRG traversal agent 124 may use the relationships between reports as provided by the TDRG 216 to generate one or more sub-task plans 222 for retrieving information from reports corresponding to nodes of the TDRG 216.

The method 300, at block B308, includes processing the plurality of sub-tasks based at least on traversing the plurality of nodes of the relation graph to identify one or more target objects from the set of objects. For example, based on the one or more sub-task plans 222, the TDRG traversal agent 124 may generate one or more report agent prompts 224 for input to the one or more expert report agents 126 to retrieve information from one or more reports of the structured report database 212, obtaining data for the query response 132 by jumping between the data provided by the individual report files 118 based on traversing the TDRG 216. The TDRG traversal agent 124 may include several functions for leveraging the relationships between reports indicated by the TDRG 216. As discussed above, the TDRG traversal agent 124 is able to move between different reports of the structured report database 212 using the TDRG 216 as a roadmap that indicates the relationships between the reports. For different types of reports, the multi-file report analysis agent 120 may comprise a respective specific expert report agent 126 that is designed to query that specific report type in order to obtain a relevant response (e.g., sub-task response data 230) to a report agent prompt 224.

The method 300, at block B310, includes constructing data retrieval code comprising an algorithm to query a first target object of the one or more target objects based at least on a first sub-task of the plurality of sub-tasks directed to the first target object. The method may include constructing the data retrieval code based at least on agentic retrieval-augmented generation (RAG) using at least one language model and a library of reference code samples.

In some embodiments, an expert report agent 126 may function as a variation of an agentic RAG model to execute LLM-based code generation to produce data retrieval code 228 to retrieve concise and relevant information from a report of the structured report database 212 (e.g., relevant to performing a sub-task as represented by a report agent prompt 224). An expert report agent 126, based on the report agent prompt 224 specified by the TDRG traversal agent 124, may generate data retrieval code 228 of a specified format (e.g., such as but not limited to Python code) providing an algorithm that may be executed by the multi-file report analysis agent 120 to query the specified report from the structured report database 212. The expert report agent 126 may generate flexible and adaptable code to answer the query indicated by the report agent prompt 224 by accessing a report of the structured report database 212 according to the specific sub-task requirements. As such, the expert report agent 126 (and/or LLMs used to implement the expert report agent 126) may answer a sub-task based on a relevant portion of a full report table, without the need to process a full report table at one time. A data retrieval code 228 generated by an expert report agent 126 may be used to process specific tables of a report (specific rows and columns) and perform various operations (analytics) and/or computations through the data retrieval code. The TDRG traversal agent 124 may move through different nodes associated with different reports, and through report agent prompt(s) 224, may call on corresponding expert report agents 126 to generate the data retrieval code 228 for retrieving the relevant information from that report. Note that in some embodiments, the data retrieval codes from different expert report agents may be executed simultaneously and/or work in parallel to perform data retrieval and analysis computations from different reports at the same time, increasing the efficiency of gathering data for producing the query response 132.

The method 300, at block B312, includes executing the data retrieval code to generate a response to the query of the first target object. After retrieving the report information from the structured report database 212 for a final result for a sub-task, the expert report agents 126 may summarize the retrieved information and provide the answer to the report agent prompts 224 back to the TDRG traversal agent 124 as sub-task response data 230. In some embodiments, the TDRG traversal agent 124 may proceed to perform a response data traversal 232 to again traverse the TDRG 216 to prompt another expert report agent 126 using information from sub-task response data 230 retrieved by a previously prompted expert report agent 126.

As previously discussed in some embodiments, the data retrieval codes from different expert report agents may be executed simultaneously and/or work in parallel to perform data retrieval and analysis computations from different reports at the same time, increasing the efficiency of gathering data for producing the query response 132. The method may therefore, in some embodiments, comprise constructing a second data retrieval code comprising a second algorithm to query a second target object of the one or more target objects based at least on a second sub-task of the plurality of sub-tasks directed to the second target object; executing the second data retrieval code to generate a response to the query of the second target object; and generating the output comprising the response to the evaluation task input based at least on the response to the query of the first target object and the query of the second target object. The second data retrieval code may be run in parallel with the data retrieval code.

The method 300, at block B314, includes generating an output comprising a response to the evaluation task input based at least on the response to the query of the first target object. Response data generated by the one or more expert report agents 126 may be consolidated and summarized and reported back to the user as a query response 132. Once a complete set of sub-task response data 230 has been obtained (e.g., the one or more sub-task plans 222 have been completed), the TDRG traversal agent 124 may produce response data summaries 234 that summarize the sub-task response data 230 results obtained from the respective expert report agent(s) 126, sending the resulting response data summaries 234 to the MCMM planner agent 122. The MCMM planner agent 122 may then analyze and compile the response data summaries 234 for each planned corner and mode, generating a comprehensive final answer for use as the query response 132.

In some embodiments, the method may include executing a first language model-based agent to decompose the evaluation task input into the mode plan, executing a second language model-based agent to traverse the plurality of nodes of the relation graph based on the mode plan to identify the one or more target objects, and executing a third language model-based agent to generate the data retrieval code based at least on the first sub-task and in response to identification of the first target object by the second language model-based agent. The second language model-based agent may output a first result summary to the first language model-based agent based at least on the response to the query of the first target object produced using the data retrieval code, and the first language model-based agent may output the response to the evaluation task input based at least on the first result summary and one or more other result summaries from the one or more target objects. In some embodiments, one or more large language models (LLMs) may be executed to instantiate the first language model-based agent, the second language model-based agent, and the third language model-based agent. At least one of the first language model-based agent, the second language model-based agent, and the third language model-based agent may be activated based on prompt inputs to the LLM. For example, one or more of the MCMM planner agent 122, TDRG traversal agent 124, and/or one or more expert report agents 126 may be implemented using one or more such language models. In some embodiments, the various distinct agents of the multi-file report analysis agent 120 may be implemented by an LLM, where an individual agent is invoked within the LLM based on the prompt input to the LLM. That is, the LLM may effectively implement a particular component agent of the multi-file report analysis agent 120 dynamically based on a prompt comprising an output from a prior agent (e.g., the MCMM planner agent may provide a prompt to the TDRG traversal agent, which may provide one or more prompts to the expert report agents). In some embodiments, one or more of the MCMM planner agent 122, TDRG traversal agent 124, and/or one or more expert report agents 126 may comprise a generative language model system 400 as described with respect to FIGS. 4A to 4C.

In some embodiments, the systems and methods described herein may be performed within, or in conjunction with, a simulation environment (e.g., NVIDIA's DriveSIM) using simulated data (e.g., simulated sensor data of simulated sensors of a virtual or simulated machine). The simulation environment may use image data to perform operations (e.g., navigating) associated with the virtual machine within the environment. These simulated operations may be used to test performance of the underlying algorithms, systems, and/or processes prior to deploying them in the real world. In some instances, the simulation may be used to generate synthetic training data—e.g., training data including regions of interest and/or subregions of interest from within the simulation. The synthetic training data (in addition to or alternatively from real-world data) may then be processed to determine geometry and/or other information related to road surfaces, for example. In any example, such as where a simulation environment is used for testing, validation, training, etc., the simulation environment and/or associated training data may be rendered or otherwise generated using one or more light transport algorithms—such as ray-tracing and/or path-tracing algorithms. In some embodiments, the simulation environment and/or one or more objects, features, or components thereof may be generated or managed within a three-dimensional (3D) content collaboration platform (e.g., NVIDIA's Omniverse) for industrial digitalization, generative physical artificial intelligence (AI), and/or other use cases, applications, or services. For example, the content collaboration platform or system may include a system for using or developing a universal scene descriptor (USD) (e.g., OpenUSD) data for managing objects, features, scenes, etc., within a simulated environment, digital environment, etc. The platform may include real physics simulation, such as using NVIDIA's PhysX SDK, in order to simulate real physics and physical interactions with simulations hosted by the platform. The platform may integrate OpenUSD along with ray tracing/path tracing/light transport simulation (e.g., NVIDIA's RTX rendering technologies) into software tools and simulation workflows for building, training, deploying, or testing AI systems such as systems for testing, validating, training (e.g., machine learning models, neural networks, etc.), and/or other tasks related to automotive, robot, machine, or other applications.

In some examples, the machine learning model(s) (e.g., deep neural networks, language models, LLMs, vision language models (VLMs), multimodal language models, perception models, tracking models, fusion models, transformer models, diffusion models, encoder-only models, decoder-only models, encoder-decoder models, neural rendering field (NeRF) models, etc.) described herein may be packaged as one or more cloud-hosted microservices—such as one or more inference microservice(s) (e.g., NVIDIA NIMs)—which may include a container (e.g., an operating system (OS)-level virtualization package) that may include an application programming interface (API) layer, a server layer, a runtime layer, and/or a model “engine.” For example, the inference microservice may include the container itself and the model(s) (e.g., weights and biases). In some instances, such as where the machine learning model(s) is small enough (e.g., has a small enough number of parameters), the model(s) may be included within the container itself. In other examples-such as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs—such as representational state transfer (REST) APIs. As such, and in some embodiments, the machine learning model(s) described herein may be deployed as an inference microservice to accelerate deployment of a model(s) on any cloud, data center, or edge computing system, while ensuring the data is secure. For example, the inference microservice may include one or more APIs, a preconfigured container for simplified deployment, an optimized inference engine (e.g., built using a standardized AI model deployment and execution software, such as NVIDIA's Triton Inference Server, and/or one or more APIs for high-performance deep learning inference, which may include an inference runtime and model optimizations that deliver low latency and high throughput for production applications—such as NVIDIA's TensorRT), and/or enterprise management data for telemetry (e.g., including identity, metrics, health checks, and/or monitoring). The machine learning model(s) described herein may be included as part of the microservice along with an accelerated infrastructure with the ability to deploy with a single command and/or orchestrate and auto-scale with a container orchestration system on accelerated infrastructure (e.g., on a single device or up to data-center scale). As such, the inference microservice may include the machine learning model(s) (e.g., that has been optimized for high-performance inference), an inference runtime software to execute the machine learning model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the machine learning model(s). When replacing or updating, the software that performs the replacement/updating may maintain user configurations of the inference runtime software and enterprise management software.

The systems and methods described herein may be used for a variety of purposes, by way of example and without limitation, for machine (e.g., robot, vehicle, construction machinery, warehouse vehicles/machines, autonomous, semi-autonomous, and/or other machine types) control, machine locomotion, machine driving, synthetic data generation, model training (e.g., using real, augmented, and/or synthetic data, such as synthetic data generated using a simulation platform or system, synthetic data generation techniques such as but not limited to those described herein, etc.), perception, augmented reality (AR), virtual reality (VR), mixed reality (MR), robotics, security and surveillance (e.g., in a smart cities implementation), autonomous or semi-autonomous machine applications, deep learning, environment simulation, object or actor simulation and/or digital twinning, data center processing, conversational AI, light transport simulation (e.g., ray-tracing, path tracing, etc.), distributed or collaborative content creation for 3D assets (e.g., using universal scene descriptor (USD) data, such as OpenUSD, and/or other data types), cloud computing, generative artificial intelligence (e.g., using one or more diffusion models, transformer models, etc.), and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot or robotic platform, aerial systems, medial systems, boating systems, smart area monitoring systems, systems for performing deep learning operations, systems for performing simulation operations (e.g., in a driving or vehicle simulation, in a robotics simulation, in a smart cities or surveillance simulation, etc.), systems for performing digital twin operations (e.g., in conjunction with a collaborative content creation platform or system, such as, without limitation, NVIDIA's OMNIVERSE and/or another platform, system, or service that uses USD or OpenUSD data types), systems implemented using an edge device, systems incorporating one or more virtual machines (VMs), systems for performing synthetic data generation operations (e.g., using one or more neural rendering fields (NERFs), gaussian splat techniques, diffusion models, transformer models, etc.), systems implemented at least partially in a data center, systems for performing conversational AI operations, systems implementing one or more language models-such as one or more large language models (LLMs), one or more vision language models (VLMs), one or more multi-modal language models, etc., systems for performing light transport simulation, systems for performing collaborative content creation for 3D assets (e.g., using universal scene descriptor (USD) data, such as OpenUSD, computer aided design (CAD) data, 2D and/or 3D graphics or design data, and/or other data types), systems implemented at least partially using cloud computing resources, and/or other types of systems.

### Example Language Models

In at least some embodiments, language models, such as large language models (LLMs), vision language models (VLMs), multi-modal language models (MMLMs), and/or other types of generative artificial intelligence (AI) may be implemented. These models may be capable of understanding, summarizing, translating, and/or otherwise generating text (e.g., natural language text, code, etc.), images, video, computer aided design (CAD) assets, OMNIVERSE and/or METAVERSE file information (e.g., in USD format, such as OpenUSD), and/or the like, based on the context provided in input prompts or queries. These language models may be considered “large,” in embodiments, based on the models being trained on massive datasets and having architectures with large number of learnable network parameters (weights and biases)—such as millions or billions of parameters. The LLMs/VLMs/MMLMs/etc. may be implemented for summarizing textual data, analyzing and extracting insights from data (e.g., textual, image, video, etc.), and generating new text/image/video/etc. in user-specified styles, tones, and/or formats. The LLMs/VLMs/MMLMs/etc. of the present disclosure may be used exclusively for text processing, in embodiments, whereas in other embodiments, multi-modal LLMs may be implemented to accept, understand, and/or generate text and/or other types of content like images, audio, 2D and/or 3D data (e.g., in USD formats), and/or video. For example, vision language models (VLMs), or more generally multi-modal language models (MMLMs), may be implemented to accept image, video, audio, textual, 3D design (e.g., CAD), and/or other inputs data types and/or to generate or output image, video, audio, textual, 3D design, and/or other output data types. In some embodiments, one or more aspects of the multi-file report analysis agent 120, MCMM planner agent 122, TDRG traversal agent 124, and/or expert report agent 126 described here may be performed by such LLMs/VLMs/MMLMs/etc. architectures.

Various types of LLMs/VLMs/MMLMs/etc. architectures may be implemented in various embodiments. For example, different architectures may be implemented that use different techniques for understanding and generating outputs—such as text, audio, video, image, 2D and/or 3D design or asset data, etc. In some embodiments, LLMs/VLMs/MMLMs/etc. architectures such as recurrent neural networks (RNNs) or long short-term memory networks (LSTMs) may be used, while in other embodiments transformer architectures—such as those that rely on self-attention and/or cross-attention (e.g., between contextual data and textual data) mechanisms—may be used to understand and recognize relationships between words or tokens and/or contextual data (e.g., other text, video, image, design data, USD, etc.). One or more generative processing pipelines that include LLMs/VLMs/MMLMs/etc. may also include one or more diffusion block(s) (e.g., denoisers). The LLMs/VLMs/MMLMs/etc. of the present disclosure may include encoder and/or decoder block(s). For example, discriminative or encoder-only models like BERT (Bidirectional Encoder Representations from Transformers) may be implemented for tasks that involve language comprehension such as classification, sentiment analysis, question answering, and named entity recognition. As another example, generative or decoder-only models like GPT (Generative Pretrained Transformer) may be implemented for tasks that involve language and content generation such as text completion, story generation, and dialogue generation. LLMs/VLMs/MMLMs/etc. that include both encoder and decoder components like T5 (Text-to-Text Transformer) may be implemented to understand and generate content, such as for translation and summarization. These examples are not intended to be limiting, and any architecture type including but not limited to those described herein—may be implemented depending on the particular embodiment and the task(s) being performed using the LLMs/VLMs/MMLMs/etc.

In various embodiments, the LLMs/VLMs/MMLMs/etc. may be trained using unsupervised learning, in which an LLMs/VLMs/MMLMs/etc. learns patterns from large amounts of unlabeled text/audio/video/image/design/USD/etc. data. Due to the extensive training, in embodiments, the models may not require task-specific or domain-specific training. LLMs/VLMs/MMLMs/etc. that have undergone extensive pre-training on vast amounts of unlabeled data may be referred to as foundation models and may be adept at a variety of tasks like question-answering, summarization, filling in missing information, translation, image/video/design/USD/data generation. Some LLMs/VLMs/MMLMs/etc. may be tailored for a specific use case using techniques like prompt tuning, fine-tuning, retrieval augmented generation (RAG), adding adapters (e.g., customized neural networks, and/or neural network layers, that tune or adjust prompts or tokens to bias the language model toward a particular task or domain), and/or using other fine-tuning or tailoring techniques that optimize the models for use on particular tasks and/or within particular domains.

In some embodiments, the LLMs/VLMs/MMLMs/etc. of the present disclosure may be implemented using various model alignment techniques. For example, in some embodiments, guardrails may be implemented to identify improper or undesired inputs (e.g., prompts) and/or outputs of the models. In doing so, the system may use the guardrails and/or other model alignment techniques to either prevent a particular undesired input from being processed using the LLMs/VLMs/MMLMs/etc., and/or preventing the output or presentation (e.g., display, audio output, etc.) of information generating using the LLMs/VLMs/MMLMs/etc. In some embodiments, one or more additional models—or layers thereof—may be implemented to identify issues with inputs and/or outputs of the models. For example, these “safeguard” models may be trained to identify inputs and/or outputs that are “safe” or otherwise okay or desired and/or that are “unsafe” or are otherwise undesired for the particular application/implementation. As a result, the LLMs/VLMs/MMLMs/etc. of the present disclosure may be less likely to output language/text/audio/video/design data/USD data/etc. that may be offensive, vulgar, improper, unsafe, out of domain, and/or otherwise undesired for the particular application/implementation.

In some embodiments, the LLMs/VLMs/etc. may be configured to or capable of accessing or using one or more plug-ins, application programming interfaces (APIs), databases, data stores, repositories, etc. For example, for certain tasks or operations that the model is not ideally suited for, the model may have instructions (e.g., as a result of training, and/or based on instructions in a given prompt) to access one or more plug-ins (e.g., 3^{rd} party plugins) for help in processing the current input. In such an example, where at least part of a prompt is related to restaurants or weather, the model may access one or more restaurant or weather plug-ins (e.g., via one or more APIs) to retrieve the relevant information. As another example, where at least part of a response requires a mathematical computation, the model may access one or more math plug-ins or APIs for help in solving the problem(s), and may then use the response from the plug-in and/or API in the output from the model. This process may be repeated—e.g., recursively—for any number of iterations and using any number of plug-ins and/or APIs until a response to the input prompt can be generated that addresses each ask/question/request/process/operation/etc. As such, the model(s) may not only rely on its own knowledge from training on a large dataset(s), but also on the expertise or optimized nature of one or more external resources-such as APIs, plug-ins, and/or the like.

In some embodiments, multiple language models (e.g., LLMs/VLMs/MMLMs/etc., multiple instances of the same language model, and/or multiple prompts provided to the same language model or instance of the same language model may be implemented, executed, or accessed (e.g., using one or more plug-ins, user interfaces, APIs, databases, data stores, repositories, etc.) to provide output responsive to the same query, or responsive to separate portions of a query. In at least one embodiment, multiple language models e.g., language models with different architectures, language models trained on different (e.g., updated) corpuses of data may be provided with the same input query and prompt (e.g., set of constraints, conditioners, etc.). In one or more embodiments, the language models may be different versions of the same foundation model. In one or more embodiments, at least one language model may be instantiated as multiple agents—e.g., more than one prompt may be provided to constrain, direct, or otherwise influence a style, a content, or a character, etc., of the output provided. In one or more example, non-limiting embodiments, the same language model may be asked to provide output corresponding to a different role, perspective, character, or having a different base of knowledge, etc.—as defined by a supplied prompt.

In any one of such embodiments, the output of two or more (e.g., each) language models, two or more versions of at least one language model, two or more instanced agents of at least one language model, and/or two more prompts provided to at least one language model may be further processed, e.g., aggregated, compared or filtered against, or used to determine (and provide) a consensus response. In one or more embodiments, the output from one language model —or version, instance, or agent—maybe be provided as input to another language model for further processing and/or validation. In one or more embodiments, a language model may be asked to generate or otherwise obtain an output with respect to an input source material, with the output being associated with the input source material. Such an association may include, for example, the generation of a caption or portion of text that is embedded (e.g., as metadata) with an input source text or image. In one or more embodiments, an output of a language model may be used to determine the validity of an input source material for further processing, or inclusion in a dataset. For example, a language model may be used to assess the presence (or absence) of a target word in a portion of text or an object in an image, with the text or image being annotated to note such presence (or lack thereof). Alternatively, the determination from the language model may be used to determine whether the source material should be included in a curated dataset, for example and without limitation.

FIG. 4A is a block diagram of an example generative language model system 400 suitable for use in implementing at least some embodiments of the present disclosure. In the example illustrated in FIG. 4A, the generative language model system 400 includes a retrieval augmented generation (RAG) component 492, an input processor 405, a tokenizer 410, an embedding component 420, plug-ins/APIs 495, and a generative language model (LM) 430 (which may include an LLM, a VLM, a multi-modal LM, etc.). In some embodiments, one or more aspects of the multi-file report analysis agent 120, MCMM planner agent 122, TDRG traversal agent 124, and/or expert report agent 126 described here may be performed by generative language model system 400.

At a high level, the input processor 405 may receive an input 401 comprising text and/or other types of input data (e.g., audio data, video data, image data, sensor data (e.g., LiDAR, RADAR, ultrasonic, etc.), 3D design data, CAD data, universal scene descriptor (USD) data—such as OpenUSD, etc.), depending on the architecture of the generative LM 430 (e.g., LLM/VLM/MMLM/etc.). In some embodiments, the input 401 includes plain text in the form of one or more sentences, paragraphs, and/or documents. Additionally or alternatively, the input 401 may include numerical sequences, precomputed embeddings (e.g., word or sentence embeddings), and/or structured data (e.g., in tabular formats, JSON, or XML). In some implementations in which the generative LM 430 is capable of processing multi-modal inputs, the input 401 may combine text (or may omit text) with image data, audio data, video data, design data, USD data, and/or other types of input data, such as but not limited to those described herein. Taking raw input text as an example, the input processor 405 may prepare raw input text in various ways. For example, the input processor 405 may perform various types of text filtering to remove noise (e.g., special characters, punctuation, HTML tags, stopwords, portions of an image(s), portions of audio, etc.) from relevant textual content. In an example involving stopwords (common words that tend to carry little semantic meaning), the input processor 405 may remove stopwords to reduce noise and focus the generative LM 430 on more meaningful content. The input processor 405 may apply text normalization, for example, by converting all characters to lowercase, removing accents, and/or or handling special cases like contractions or abbreviations to ensure consistency. These are just a few examples, and other types of input processing may be applied.

In some embodiments, a RAG component 492 (which may include one or more RAG models, and/or may be performed using the generative LM 430 itself) may be used to retrieve additional information to be used as part of the input 401 or prompt. RAG may be used to enhance the input to the LLM/VLM/MMLM/etc. with external knowledge, so that answers to specific questions or queries or requests are more relevant—such as in a case where specific knowledge is required. The RAG component 492 may fetch this additional information (e.g., grounding information, such as grounding text/image/video/audio/USD/CAD/etc.) from one or more external sources, which can then be fed to the LLM/VLM/MMLM/etc. along with the prompt to improve accuracy of the responses or outputs of the model.

For example, in some embodiments, the input 401 may be generated using the query or input to the model (e.g., a question, a request, etc.) in addition to data retrieved using the RAG component 492. In some embodiments, the input processor 405 may analyze the input 401 and communicate with the RAG component 492 (or the RAG component 492 may be part of the input processor 405, in embodiments) in order to identify relevant text and/or other data to provide to the generative LM 430 as additional context or sources of information from which to identify the response, answer, or output 490, generally. For example, where the input indicates that the user is interested in a desired tire pressure for a particular make and model of vehicle, the RAG component 492 may retrieve-using a RAG model performing a vector search in an embedding space, for example-the tire pressure information or the text corresponding thereto from a digital (embedded) version of the user manual for that particular vehicle make and model. Similarly, where a user revisits a chatbot related to a particular product offering or service, the RAG component 492 may retrieve a prior stored conversation history—or at least a summary thereof—and include the prior conversation history along with the current ask/request as part of the input 401 to the generative LM 430.

The RAG component 492 may use various RAG techniques. For example, naïve RAG may be used where documents are indexed, chunked, and applied to an embedding model to generate embeddings corresponding to the chunks. A user query may also be applied to the embedding model and/or another embedding model of the RAG component 492 and the embeddings of the chunks along with the embeddings of the query may be compared to identify the most similar/related embeddings to the query, which may be supplied to the generative LM 430 to generate an output.

In some embodiments, more advanced RAG techniques may be used. For example, prior to passing chunks to the embedding model, the chunks may undergo pre-retrieval processes (e.g., routing, rewriting, metadata analysis, expansion, etc.). In addition, prior to generating the final embeddings, post-retrieval processes (e.g., re-ranking, prompt compression, etc.) may be performed on the outputs of the embedding model prior to final embeddings being used as comparison to an input query.

As a further example, modular RAG techniques may be used, such as those that are similar to naïve and/or advanced RAG, but also include features such as hybrid search, recursive retrieval and query engines, StepBack approaches, sub-queries, and hypothetical document embedding.

As another example, Graph RAG may use knowledge graphs as a source of context or factual information. Graph RAG may be implemented using a graph database as a source of contextual information sent to the LLM/VLM/MMLM/etc. Rather than (or in addition to) providing the model with chunks of data extracted from larger sized documents—which may result in a lack of context, factual correctness, language accuracy, etc.—graph RAG may also provide structured entity information to the LLM/VLM/MMLM/etc. by combining the structured entity textual description with its many properties and relationships, allowing for deeper insights by the model. When implementing graph RAG, the systems and methods described herein use a graph as a content store and extract relevant chunks of documents and ask the LLM/VLM/MMLM/etc. to answer using them. The knowledge graph, in such embodiments, may contain relevant textual content and metadata about the knowledge graph as well as be integrated with a vector database. In some embodiments, the graph RAG may use a graph as a subject matter expert, where descriptions of concepts and entities relevant to a query/prompt may be extracted and passed to the model as semantic context. These descriptions may include relationships between the concepts. In other examples, the graph may be used as a database, where part of a query/prompt may be mapped to a graph query, the graph query may be executed, and the LLM/VLM/MMLM/etc. may summarize the results. In such an example, the graph may store relevant factual information, and a query (natural language query) to graph query tool (NL-to-Graph-query tool) and entity linking may be used. In some embodiments, graph RAG (e.g., using a graph database) may be combined with standard (e.g., vector database) RAG, and/or other RAG types, to benefit from multiple approaches.

In any embodiments, the RAG component 492 may implement a plugin, API, user interface, and/or other functionality to perform RAG. For example, a graph RAG plug-in may be used by the LLM/VLM/MMLM/etc. to run queries against the knowledge graph to extract relevant information for feeding to the model, and a standard or vector RAG plug-in may be used to run queries against a vector database. For example, the graph database may interact with a plug-in's REST interface such that the graph database is decoupled from the vector database and/or the embeddings models.

The tokenizer 410 may segment the (e.g., processed) text data into smaller units (tokens) for subsequent analysis and processing. The tokens may represent individual words, subwords, characters, portions of audio/video/image/etc., depending on the implementation. Word-based tokenization divides the text into individual words, treating each word as a separate token. Subword tokenization breaks down words into smaller meaningful units (e.g., prefixes, suffixes, stems), enabling the generative LM 430 to understand morphological variations and handle out-of-vocabulary words more effectively. Character-based tokenization represents each character as a separate token, enabling the generative LM 430 to process text at a fine-grained level. The choice of tokenization strategy may depend on factors such as the language being processed, the task at hand, and/or characteristics of the training dataset. As such, the tokenizer 410 may convert the (e.g., processed) text into a structured format according to tokenization schema being implemented in the particular embodiment.

The embedding component 420 may use any known embedding technique to transform discrete tokens into (e.g., dense, continuous vector) representations of semantic meaning. For example, the embedding component 420 may use pre-trained word embeddings (e.g., Word2Vec, GloVe, or FastText), one-hot encoding, Term Frequency-Inverse Document Frequency (TF-IDF) encoding, one or more embedding layers of a neural network, and/or otherwise.

In some implementations in which the input 401 includes image data/video data/etc., the input processor 401 may resize the data to a standard size compatible with format of a corresponding input channel and/or may normalize pixel values to a common range (e.g., 0 to 1) to ensure a consistent representation, and the embedding component 420 may encode the image data using any known technique (e.g., using one or more convolutional neural networks (CNNs) to extract visual features). In some implementations in which the input 401 includes audio data, the input processor 401 may resample an audio file to a consistent sampling rate for uniform processing, and the embedding component 420 may use any known technique to extract and encode audio features-such as in the form of a spectrogram (e.g., a mel-spectrogram). In some implementations in which the input 401 includes video data, the input processor 401 may extract frames or apply resizing to extracted frames, and the embedding component 420 may extract features such as optical flow embeddings or video embeddings and/or may encode temporal information or sequences of frames. In some implementations in which the input 401 includes multi-modal data, the embedding component 420 may fuse representations of the different types of data (e.g., text, image, audio, USD, video, design, etc.) using techniques like early fusion (concatenation), late fusion (sequential processing), attention-based fusion (e.g., self-attention, cross-attention), etc.

The generative LM 430 and/or other components of the generative LM system 400 may use different types of neural network architectures depending on the implementation. For example, transformer-based architectures such as those used in models like GPT may be implemented, and may include self-attention mechanisms that weigh the importance of different words or tokens in the input sequence and/or feedforward networks that process the output of the self-attention layers, applying non-linear transformations to the input representations and extracting higher-level features. Some non-limiting example architectures include transformers (e.g., encoder-decoder, decoder only, multi-modal), RNNs, LSTMs, fusion models, diffusion models, cross-modal embedding models that learn joint embedding spaces, graph neural networks (GNNs), hybrid architectures combining different types of architectures adversarial networks like generative adversarial networks or GANs or adversarial autoencoders (AAEs) for joint distribution learning, and others. As such, depending on the implementation and architecture, the embedding component 420 may apply an encoded representation of the input 401 to the generative LM 430, and the generative LM 430 may process the encoded representation of the input 401 to generate an output 490, which may include responsive text and/or other types of data.

As described herein, in some embodiments, the generative LM 430 may be configured to access or use—or capable of accessing or using—plug-ins/APIs 495 (which may include one or more plug-ins, application programming interfaces (APIs), databases, data stores, repositories, etc.). For example, for certain tasks or operations that the generative LM 430 is not ideally suited for, the model may have instructions (e.g., as a result of training, and/or based on instructions in a given prompt, such as those retrieved using the RAG component 492) to access one or more plug-ins/APIs 495 (e.g., 3^{rd} party plugins) for help in processing the current input. In such an example, where at least part of a prompt is related to restaurants or weather, the model may access one or more restaurant or weather plug-ins (e.g., via one or more APIs), send at least a portion of the prompt related to the particular plug-in/API 495 to the plug-in/API 495, the plug-in/API 495 may process the information and return an answer to the generative LM 430, and the generative LM 430 may use the response to generate the output 490. This process may be repeated —e.g., recursively—for any number of iterations and using any number of plug-ins/APIs 495 until an output 490 that addresses each ask/question/request/process/operation/etc. from the input 401 can be generated. As such, the model(s) may not only rely on its own knowledge from training on a large dataset(s) and/or from data retrieved using the RAG component 492, but also on the expertise or optimized nature of one or more external resources—such as the plug-ins/APIs 495.

FIG. 4B is a block diagram of an example implementation in which the generative LM 430 includes a transformer encoder-decoder. For example, assume input text such as “Who discovered gravity” is tokenized (e.g., by the tokenizer 410 of FIG. 4A) into tokens such as words, and each token is encoded (e.g., by the embedding component 420 of FIG. 4A) into a corresponding embedding (e.g., of size 512). Since these token embeddings typically do not represent the position of the token in the input sequence, any known technique may be used to add a positional encoding to each token embedding to encode the sequential relationships and context of the tokens in the input sequence. As such, the (e.g., resulting) embeddings may be applied to one or more encoder(s) 435 of the generative LM 430.

In an example implementation, the encoder(s) 435 forms an encoder stack, where each encoder includes a self-attention layer and a feedforward network. In an example transformer architecture, each token (e.g., word) flows through a separate path. As such, each encoder may accept a sequence of vectors, passing each vector through the self-attention layer, then the feedforward network, and then upwards to the next encoder in the stack. Any known self-attention technique may be used. For example, to calculate a self-attention score for each token (word), a query vector, a key vector, and a value vector may be created for each token, a self-attention score may be calculated for pairs of tokens by taking the dot product of the query vector with the corresponding key vectors, normalizing the resulting scores, multiplying by corresponding value vectors, and summing weighted value vectors. The encoder may apply multi-headed attention in which the attention mechanism is applied multiple times in parallel with different learned weight matrices. Any number of encoders may be cascaded to generate a context vector encoding the input. An attention projection layer 440 may convert the context vector into attention vectors (keys and values) for the decoder(s) 445.

In an example implementation, the decoder(s) 445 form a decoder stack, where each decoder includes a self-attention layer, an encoder-decoder self-attention layer that uses the attention vectors (keys and values) from the encoder to focus on relevant parts of the input sequence, and a feedforward network. As with the encoder(s) 435, in an example transformer architecture, each token (e.g., word) flows through a separate path in the decoder(s) 445. During a first pass, the decoder(s) 445, a classifier 450, and a generation mechanism 455 may generate a first token, and the generation mechanism 455 may apply the generated token as an input during a second pass. The process may repeat in a loop, successively generating and adding tokens (e.g., words) to the output from the preceding pass and applying the token embeddings of the composite sequence with positional encodings as an input to the decoder(s) 445 during a subsequent pass, sequentially generating one token at a time (known as auto-regression) until predicting a symbol or token that represents the end of the response. Within each decoder, the self-attention layer is typically constrained to attend only to preceding positions in the output sequence by applying a masking technique (e.g., setting future positions to negative infinity) before the softmax operation. In an example implementation, the encoder-decoder attention layer operates similarly to the (e.g., multi-headed) self-attention in the encoder(s) 435, except that it creates its queries from the layer below it and takes the keys and values (e.g., matrix) from the output of the encoder(s) 435.

As such, the decoder(s) 445 may output some decoded (e.g., vector) representation of the input being applied during a particular pass. The classifier 450 may include a multi-class classifier comprising one or more neural network layers that project the decoded (e.g., vector) representation into a corresponding dimensionality (e.g., one dimension for each supported word or token in the output vocabulary) and a softmax operation that converts logits to probabilities. As such, the generation mechanism 455 may select or sample a word or token based on a corresponding predicted probability (e.g., select the word with the highest predicted probability) and append it to the output from a previous pass, generating each word or token sequentially. The generation mechanism 455 may repeat the process, triggering successive decoder inputs and corresponding predictions until selecting or sampling a symbol or token that represents the end of the response, at which point, the generation mechanism 455 may output the generated response.

FIG. 4C is a block diagram of an example implementation in which the generative LM 430 includes a decoder-only transformer architecture. For example, the decoder(s) 460 of FIG. 4C may operate similarly as the decoder(s) 445 of FIG. 4B except each of the decoder(s) 460 of FIG. 4C omits the encoder-decoder self-attention layer (since there is no encoder in this implementation). As such, the decoder(s) 460 may form a decoder stack, where each decoder includes a self-attention layer and a feedforward network. Furthermore, instead of encoding the input sequence, a symbol or token representing the end of the input sequence (or the beginning of the output sequence) may be appended to the input sequence, and the resulting sequence (e.g., corresponding embeddings with positional encodings) may be applied to the decoder(s) 460. As with the decoder(s) 445 of FIG. 4B, each token (e.g., word) may flow through a separate path in the decoder(s) 460, and the decoder(s) 460, a classifier 465, and a generation mechanism 470 may use auto-regression to sequentially generate one token at a time until predicting a symbol or token that represents the end of the response. The classifier 465 and the generation mechanism 470 may operate similarly as the classifier 450 and the generation mechanism 455 of FIG. 4B, with the generation mechanism 470 selecting or sampling each successive output token based on a corresponding predicted probability and appending it to the output from a previous pass, generating each token sequentially until selecting or sampling a symbol or token that represents the end of the response. These and other architectures described herein are meant simply as examples, and other suitable architectures may be implemented within the scope of the present disclosure.

### Example Computing Device

FIG. 5 is a block diagram of an example computing device(s) 500 suitable for use in implementing some embodiments of the present disclosure. Computing device 500 may include an interconnect system 502 that directly or indirectly couples the following devices: memory 504, one or more central processing units (CPUs) 506, one or more graphics processing units (GPUs) 508, a communication interface 510, input/output (I/O) ports 512, input/output components 514, a power supply 516, one or more presentation components 518 (e.g., display(s)), and one or more logic units 520. In at least one embodiment, the computing device(s) 500 may comprise one or more virtual machines (VMs), and/or any of the components thereof may comprise virtual components (e.g., virtual hardware components). For non-limiting examples, one or more of the GPUs 508 may comprise one or more vGPUs, one or more of the CPUs 506 may comprise one or more vCPUs, and/or one or more of the logic units 520 may comprise one or more virtual logic units. As such, a computing device(s) 500 may include discrete components (e.g., a full GPU dedicated to the computing device 500), virtual components (e.g., a portion of a GPU dedicated to the computing device 500), or a combination thereof. In some embodiments, one or more aspects of the multi-file report analysis agent 120, MCMM planner agent 122, TDRG traversal agent 124, and/or expert report agent 126 described here may be performed by computing device 500.

Although the various blocks of FIG. 5 are shown as connected via the interconnect system 502 with lines, this is not intended to be limiting and is for clarity only. For example, in some embodiments, a presentation component 518, such as a display device, may be considered an I/O component 514 (e.g., if the display is a touch screen). As another example, the CPUs 506 and/or GPUs 508 may include memory (e.g., the memory 504 may be representative of a storage device in addition to the memory of the GPUs 508, the CPUs 506, and/or other components). As such, the computing device of FIG. 5 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 5.

The interconnect system 502 may represent one or more links or busses, such as an address bus, a data bus, a control bus, or a combination thereof. The interconnect system 502 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 506 may be directly connected to the memory 504. Further, the CPU 506 may be directly connected to the GPU 508. Where there is direct, or point-to-point connection between components, the interconnect system 502 may include a PCIe link to carry out the connection. In these examples, a PCI bus need not be included in the computing device 500.

The memory 504 may include any of a variety of computer-readable media. The computer-readable media may be any available media that may be accessed by the computing device 500. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 504 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 500. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 506 may be configured to execute at least some of the computer-readable instructions to control one or more components of the computing device 500 to perform one or more of the methods and/or processes described herein. The CPU(s) 506 may each include one or more cores (e.g., one, two, four, eight, twenty-eight, seventy-two, etc.) that are capable of handling a multitude of software threads simultaneously. The CPU(s) 506 may include any type of processor, and may include different types of processors depending on the type of computing device 500 implemented (e.g., processors with fewer cores for mobile devices and processors with more cores for servers). For example, depending on the type of computing device 500, the processor may be an Advanced RISC Machines (ARM) processor implemented using Reduced Instruction Set Computing (RISC) or an x86 processor implemented using Complex Instruction Set Computing (CISC). The computing device 500 may include one or more CPUs 506 in addition to one or more microprocessors or supplementary co-processors, such as math co-processors.

In addition to or alternatively from the CPU(s) 506, the GPU(s) 508 may be configured to execute at least some of the computer-readable instructions to control one or more components of the computing device 500 to perform one or more of the methods and/or processes described herein. One or more of the GPU(s) 508 may be an integrated GPU (e.g., with one or more of the CPU(s) 506 and/or one or more of the GPU(s) 508 may be a discrete GPU. In embodiments, one or more of the GPU(s) 508 may be a coprocessor of one or more of the CPU(s) 506. The GPU(s) 508 may be used by the computing device 500 to render graphics (e.g., 3D graphics) or perform general purpose computations. For example, the GPU(s) 508 may be used for General-Purpose computing on GPUs (GPGPU). The GPU(s) 508 may include hundreds or thousands of cores that are capable of handling hundreds or thousands of software threads simultaneously. The GPU(s) 508 may generate pixel data for output images in response to rendering commands (e.g., rendering commands from the CPU(s) 506 received via a host interface). The GPU(s) 508 may include graphics memory, such as display memory, for storing pixel data or any other suitable data, such as GPGPU data. The display memory may be included as part of the memory 504. The GPU(s) 508 may include two or more GPUs operating in parallel (e.g., via a link). The link may directly connect the GPUs (e.g., using NVLINK) or may connect the GPUs through a switch (e.g., using NVSwitch). When combined together, each GPU 508 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 506 and/or the GPU(s) 508, the logic unit(s) 520 may be configured to execute at least some of the computer-readable instructions to control one or more components of the computing device 500 to perform one or more of the methods and/or processes described herein. In embodiments, the CPU(s) 506, the GPU(s) 508, and/or the logic unit(s) 520 may discretely or jointly perform any combination of the methods, processes and/or portions thereof. One or more of the logic units 520 may be part of and/or integrated in one or more of the CPU(s) 506 and/or the GPU(s) 508 and/or one or more of the logic units 520 may be discrete components or otherwise external to the CPU(s) 506 and/or the GPU(s) 508. In embodiments, one or more of the logic units 520 may be a coprocessor of one or more of the CPU(s) 506 and/or one or more of the GPU(s) 508. In some embodiments, one or more aspects of the multi-file report analysis agent 120, MCMM planner agent 122, TDRG traversal agent 124, and/or expert report agent 126 described here may be performed by CPU(s) 506, GPU(s) 508, and/or logic units 520.

Examples of the logic unit(s) 520 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Programmable Vision Accelerator (PVAs)—which may include one or more direct memory access (DMA) systems, one or more vision or vector processing units (VPUs), one or more pixel processing engines (PPEs)—e.g., including a 2D array of processing elements that each communicate north, south, east, and west with one or more other processing elements in the array, one or more decoupled accelerators or units (e.g., decoupled lookup table (DLUT) accelerators or units), etc., Vision Processing Units (VPUs), Optical Flow Accelerators (OFAs), Field Programmable Gate Arrays (FPGAs), Neuromorphic Chips, Quantum Processing Units (QPUs), Associative Process Units (APUs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 510 may include one or more receivers, transmitters, and/or transceivers that allow the computing device 500 to communicate with other computing devices via an electronic communication network, included wired and/or wireless communications. The communication interface 510 may include components and functionality to allow communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 520 and/or communication interface 510 may include one or more data processing units (DPUs) to transmit data received over a network and/or through interconnect system 502 directly to (e.g., a memory of) one or more GPU(s) 508.

The I/O ports 512 may allow the computing device 500 to be logically coupled to other devices including the I/O components 514, the presentation component(s) 518, and/or other components, some of which may be built in to (e.g., integrated in) the computing device 500. Illustrative I/O components 514 include a microphone, mouse, keyboard, joystick, game pad, game controller, satellite dish, scanner, printer, wireless device, etc. The I/O components 514 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 500. The computing device 500 may be include depth cameras, such as stereoscopic camera systems, infrared camera systems, RGB camera systems, touchscreen technology, and combinations of these, for gesture detection and recognition. Additionally, the computing device 500 may include accelerometers or gyroscopes (e.g., as part of an inertia measurement unit (IMU)) that allow detection of motion. In some examples, the output of the accelerometers or gyroscopes may be used by the computing device 500 to render immersive augmented reality or virtual reality.

The power supply 516 may include a hard-wired power supply, a battery power supply, or a combination thereof. The power supply 516 may provide power to the computing device 500 to allow the components of the computing device 500 to operate.

The presentation component(s) 518 may include a display (e.g., a monitor, a touch screen, a television screen, a heads-up-display (HUD), other display types, or a combination thereof), speakers, and/or other presentation components. The presentation component(s) 518 may receive data from other components (e.g., the GPU(s) 508, the CPU(s) 506, DPUs, etc.), and output the data (e.g., as an image, video, sound, etc.).

### Example Data Center

FIG. 6 illustrates an example data center 600 that may be used in at least one embodiments of the present disclosure. The data center 600 may include a data center infrastructure layer 610, a framework layer 620, a software layer 630, and/or an application layer 640. In some embodiments, one or more aspects of the multi-file report analysis agent 120, MCMM planner agent 122, TDRG traversal agent 124, and/or expert report agent 126 described here may be performed by data center 600.

As shown in FIG. 6, the data center infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 616(1)-616(N) may correspond to a server having one or more of the above-mentioned computing resources. In addition, in some embodiments, the node C.R.s 616(1)-6161(N) may include one or more virtual components, such as vGPUs, vCPUs, and/or the like, and/or one or more of the node C.R.s 616(1)-616(N) may correspond to a virtual machine (VM). In some embodiments, one or more aspects of the multi-file report analysis agent 120, MCMM planner agent 122, TDRG traversal agent 124, and/or expert report agent 126 described here may be performed by vGPUs, vCPUs, and/or one or more of the node C.R.s 616(1)-616(N).

In at least one embodiment, grouped computing resources 614 may include separate groupings of node C.R.s 616 housed within one or more racks (not shown), or many racks housed in data centers at various geographical locations (also not shown). Separate groupings of node C.R.s 616 within grouped computing resources 614 may include grouped compute, network, memory or storage resources that may be configured or allocated to support one or more workloads. In at least one embodiment, several node C.R.s 616 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 612 may configure or otherwise control one or more node C.R.s 616(1)-616(N) and/or grouped computing resources 614. In at least one embodiment, resource orchestrator 612 may include a software design infrastructure (SDI) management entity for the data center 600. The resource orchestrator 612 may include hardware, software, or some combination thereof.

In at least one embodiment, as shown in FIG. 6, framework layer 620 may include a job scheduler 628, a configuration manager 634, a resource manager 636, and/or a distributed file system 638. The framework layer 620 may include a framework to support software 632 of software layer 630 and/or one or more application(s) 642 of application layer 640. The software 632 or application(s) 642 may respectively include web-based service software or applications, such as those provided by Amazon Web Services, Google Cloud and Microsoft Azure. The framework layer 620 may be, but is not limited to, a type of free and open-source software web application framework such as Apache Spark™ (hereinafter “Spark”) that may use distributed file system 638 for large-scale data processing (e.g., “big data”). In at least one embodiment, job scheduler 628 may include a Spark driver to facilitate scheduling of workloads supported by various layers of data center 600. The configuration manager 634 may be capable of configuring different layers such as software layer 630 and framework layer 620 including Spark and distributed file system 638 for supporting large-scale data processing. The resource manager 636 may be capable of managing clustered or grouped computing resources mapped to or allocated for support of distributed file system 638 and job scheduler 628. In at least one embodiment, clustered or grouped computing resources may include grouped computing resource 614 at data center infrastructure layer 610. The resource manager 636 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 638 of framework layer 620. One or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 638 of framework layer 620. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 634, resource manager 636, and resource orchestrator 612 may implement any number and type of self-modifying actions based on any amount and type of data acquired in any technically feasible fashion. Self-modifying actions may relieve a data center operator of data center 600 from making possibly bad configuration decisions and possibly avoiding underutilized and/or poor performing portions of a data center.

The data center 600 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 600. In at least one embodiment, trained or deployed machine learning models corresponding to one or more neural networks may be used to infer or predict information using resources described above with respect to the data center 600 by using weight parameters calculated through one or more training techniques, such as but not limited to those described herein.

In at least one embodiment, the data center 600 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 500 of FIG. 5—e.g., each device may include similar components, features, and/or functionality of the computing device(s) 500. In addition, where backend devices (e.g., servers, NAS, etc.) are implemented, the backend devices may be included as part of a data center 600, an example of which is described in more detail herein with respect to FIG. 6.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 500 described herein with respect to FIG. 5. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. One or more processors comprising processing circuitry to:
generate a structured database based at least on a set of objects comprising a plurality of different object structures, the set of objects representing result reports of at least one circuit design analysis;
construct, based at least on the set of objects, a relation graph comprising a plurality of nodes and a plurality of edges, wherein an individual node of the plurality of nodes corresponds to an individual object of the set of objects, and an individual edge of the plurality of edges indicates a relationship between objects as indicated by at least one debugging trace;
decompose an evaluation task input into a mode plan including a plurality of subtasks directed to the set of objects;
process the plurality of sub-tasks based at least on traversing the plurality of nodes of the relation graph to identify one or more target objects from the set of objects;
construct data retrieval code comprising an algorithm to query a first target object of the one or more target objects based at least on a first sub-task of the plurality of subtasks directed to the first target object;
execute the data retrieval code to generate a response to the query of the first target object; and
generate an output comprising a response to the evaluation task input based at least on the response to the query of the first target object.

2. The one or more processors of claim 1, wherein the set of objects comprises one or more of a timing report, a multi-corner multi-mode (MCMM) timing report, or a static timing analysis (STA) report.

3. The one or more processors of claim 1, wherein the structured database comprises one or more nested dictionaries, wherein an individual dictionary of the one or more nested dictionaries corresponds to an associated object structure of the plurality of different object structures.

4. The one or more processors of claim 1, wherein the processing circuitry is further to:
construct a second data retrieval code comprising a second algorithm to query a second target object of the one or more target objects based at least on a second sub-task of the plurality of sub-tasks directed to the second target object;
execute the second data retrieval code to generate a response to the query of the second target object; and
generate the output comprising the response to the evaluation task input based at least on the response to the query of the first target object and the query of the second target object.

5. The one or more processors of claim 4, wherein the processing circuitry is further to run the second data retrieval code in parallel with the data retrieval code.

6. The one or more processors of claim 1, wherein the processing circuitry is further to:
construct the data retrieval code based at least on agentic retrieval-augmented generation (RAG) using at least one language model and a library of reference code samples.

7. The one or more processors of claim 1, wherein the at least one debugging trace indicates a generalized strategy for progressing through a set of analyses reports to perform one or more particular analysis tasks.

8. The one or more processors of claim 7, wherein the processing circuitry is further to generate the at least one debugging trace based at least on a compilation of analysis guidance documents.

9. The one or more processors of claim 1, wherein the processing circuitry is further to:
execute a first language model-based agent to decompose the evaluation task input into the mode plan;
execute a second language model-based agent to traverse the plurality of nodes of the relation graph based at least on the mode plan to identify the one or more target objects; and
execute a third language model-based agent to generate the data retrieval code based at least on the first sub-task and in response to identification of the first target object by the second language model-based agent.

10. The one or more processors of claim 9, wherein the processing circuitry is further to:
execute the second language model-based agent to output a first result summary to the first language model-based agent based at least on the response to the query of the first target object produced using the data retrieval code; and
execute the first language model-based agent to output the response to the evaluation task input based at least on the first result summary and one or more other result summaries from the one or more target objects.

11. The one or more processors of claim 9, wherein the processing circuitry is further to execute a large language model (LLM) to instantiate the first language model-based agent, the second language model-based agent, and the third language model-based agent.

12. The one or more processors of claim 11, wherein the processing circuitry is further to activate at least one of the first language model-based agent, the second language model-based agent, and the third language model-based agent based on prompt inputs to the LLM.

13. The one or more processors of claim 1, wherein the processing circuitry is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for three-dimensional assets;
a system for performing deep learning operations;
a system for performing remote operations;
a system for performing real-time streaming;
a system for generating or presenting one or more of augmented reality content, virtual reality content, or mixed reality content;
a system implemented using an edge device;
a system implemented using a robot;
a system for performing conversational AI operations;
a system implementing one or more language models;
a system implementing one or more large language models (LLMs);
a system implementing one or more vision language models (VLMs);
a system implementing one or more multimodal language models (MMLMs);
a system implemented using one or more cloud-hosted microservices;
a system for generating synthetic data;
a system for generating synthetic data using AI;
a system incorporating one or more virtual machines (VMs);
a system using or deploying one or more inference microservices;
a system that incorporates one or more machine learning models deployed in a service or microservice along with an OS-level virtualization package;
a system implemented at least partially in a data center; or
a system implemented at least partially using cloud computing resources.

14. A system comprising one or more processors to:
obtain a structured database that includes a set of objects that comprise a plurality of different object structures, the set of objects representing result reports of at least one circuit design analysis;
obtain an evaluation task input defining one or more sub-tasks directed to the set of objects;
process the one or more sub-tasks to identify one or more target objects from the set of objects, wherein the one or more sub-tasks are processed based at least on traversing a plurality of nodes of a relation graph, the relation graph comprising a graph structure based at least on the set of objects and at least one debugging trace defining one or more structured strategies for retrieving information from the structured database;
execute a data retrieval code constructed in response to identification of the one or more target objects, the data retrieval code comprising an algorithm to probe at least a first target object of the one or more target objects based at least on a first sub-task of the one or more sub-tasks directed to the first target object; and
compile an output representing a response to the evaluation task input based at least on a response to the probe of at least the first target object.

15. The system of claim 14, wherein the set of objects comprises one or more of a timing report, a multi-corner multi-mode (MCMM) timing report, or a static timing analysis (STA) report.

16. The system of claim 14, wherein the one or more processors are further to:
construct the data retrieval code based at least on agentic retrieval-augmented generation (RAG) using at least one language model and a library of reference code samples.

17. The system of claim 14, wherein the at least one debugging trace indicates a generalized strategy for progressing through a set of analyses reports to perform one or more particular analysis tasks.

18. The system of claim 14, wherein the one or more processors are further to:
execute a first language model-based agent to decompose the evaluation task input into a mode plan;
execute a second language model-based agent to traverse the plurality of nodes of the relation graph based at least on the mode plan to identify the one or more target objects; and
execute a third language model-based agent to generate the data retrieval code based at least on the first sub-task of the one or more sub-tasks and in response to identification of the first target object by the second language model-based agent.

19. The system of claim 14, wherein the system is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for three-dimensional assets;
a system for performing deep learning operations;
a system for performing remote operations;
a system for performing real-time streaming;
a system for generating or presenting one or more of augmented reality content, virtual reality content, or mixed reality content;
a system implemented using an edge device;
a system implemented using a robot;
a system for performing conversational AI operations;
a system implementing one or more language models;
a system implementing one or more large language models (LLMs);
a system implementing one or more vision language models (VLMs);
a system implementing one or more multimodal language models (MMLMs);
a system implemented using one or more cloud-hosted microservices;
a system for generating synthetic data;
a system for generating synthetic data using AI;
a system incorporating one or more virtual machines (VMs);
a system using or deploying one or more inference microservices;
a system that incorporates one or more machine learning models deployed in a service or microservice along with an OS-level virtualization package;
a system implemented at least partially in a data center; or
a system implemented at least partially using cloud computing resources.

20. A method comprising:
generating an evaluation task output in response to a query of a structured database including a set of objects comprising a plurality of different object structures and representing result reports of at least one circuit design analysis;
wherein the evaluation task output is generated based at least on:
identifying one or more target objects based at least on traversing a plurality of nodes of a relation graph, the relation graph comprising a graph structure based at least on the set of objects and a debugging trace defining one or more structured strategies for retrieving information from the structured database; and
executing a data retrieval code constructed by a language model in response to at least one prompt representing at least one sub-task of the query and an indication of the identified one or more target objects.
